(19) United States
(12) Patent Application Publication
(10) Pub. No.: US 2024/0030333 A1
(43) Pub. Date: Jan. 25, 2024

(54) NITRIDE SEMICONDUCTOR DEVICE

(71) Applicant: ROHM CO., LTD., Kyoto-shi (JP)

(72) Inventor: Kazuya NAGASE, Kyoto-shi (JP)

(73) Assignee: ROHM CO., LTD., Kyoto-shi (JP)

(21) Appl. No.: 18/220,833

(22) Filed: Jul. 12, 2023

(30) Foreign Application Priority Data
Jul. 19, 2022 (JP) 2022-114622
Jun. 12, 2023 (JP) 2023-096392

(51) Int. Cl. H01L 29/778; H01L 29/08; H01L 29/20; H01L 29/66

(52) U.S. Cl. CPC H01L 29/7786; H01L 29/0843; H01L 29/2003; H01L 29/66462

(57) ABSTRACT

A nitride semiconductor device includes an electron transit layer, an electron supply layer, a gate layer, a gate electrode, a passivation layer, a source electrode, and a drain electrode. The gate layer includes a ridge including an upper surface of the gate layer, a source-side extension smaller in thickness than the ridge, and a drain-side extension smaller in thickness than the ridge. The source-side extension includes a first step portion including an upper surface parallel to a bottom surface of the gate layer and a first intermediate portion connecting the first step portion to the ridge. The drain-side extension includes a second step portion including an upper surface parallel to the bottom surface of the gate layer and a second intermediate portion connecting the second step portion to the ridge. The first intermediate portion has a cross-sectional area that is greater than that of the second intermediate portion.

### CROSS-REFERENCE TO RELATED APPLICATIONS

This application claims priority to Japanese Patent Application Nos. 2022-114622 filed on Jul. 19, 2022 and 2023-096392 filed on Jun. 12, 2023, respectively, the entire contents of each are incorporated herein by reference.

### BACKGROUND

### 1. Field

The following description relates to a nitride semiconductor device.

### 2. Description of Related Art

A nitride semiconductor such as gallium nitride (GaN) has been used to produce a high-electron-mobility transistor (HEMT). An example of a nitride semiconductor HEMT includes an electron transit layer composed of a gallium nitride (GaN) layer and an electron supply layer composed of an aluminum gallium nitride (AlGaN) layer. When the electron transit layer and the electron supply layer form a heterojunction, two dimensional electronic gas (2DEG) is formed in the electron transit layer in the vicinity of the interface between the electron transit layer and the electron supply layer and is used as a channel of the HEMT.

When the HEMT is of a normally-off type, for example, a nitride semiconductor layer containing an acceptor impurity (e.g., p-type GaN layer) is disposed as a gate layer between a gate electrode and the electron transit layer. The acceptor impurity included in the p-type GaN layer causes the channel in the electron transit layer to disappear from the region immediately below the gate electrode. This achieves normally-off operation. Japanese Laid-Open Patent Publication No. 2017-73506 discloses such a normally-off type HEMT.

### BRIEF DESCRIPTION OF THE DRAWINGS

FIG. 1 is a schematic plan view of an exemplary nitride semiconductor device according to an embodiment.

FIG. 2 is a schematic cross-sectional view of the nitride semiconductor device taken along line F2-F2 in FIG. 1.

FIG. 3 is an enlarged partial view of FIG. 2.

FIG. 4 is a schematic cross-sectional view showing an exemplary step for manufacturing the nitride semiconductor device shown in FIG. 2.

FIG. 5 is a schematic cross-sectional view showing a manufacturing step subsequent to the step shown in FIG. 4.

FIG. 6 is a schematic cross-sectional view showing a manufacturing step subsequent to the step shown in FIG. 5.

FIG. 7 is a schematic cross-sectional view showing a manufacturing step subsequent to the step shown in FIG. 6.

FIG. 8 is a schematic cross-sectional view showing a manufacturing step subsequent to the step shown in FIG. 7.

FIG. 9 is a schematic cross-sectional view showing a manufacturing step subsequent to the step shown in FIG. 8.

FIG. 10 is a schematic cross-sectional view showing a manufacturing step subsequent to the step shown in FIG. 9.

FIG. 11 is a schematic cross-sectional view showing a manufacturing step subsequent to the step shown in FIG. 10.

FIG. 12 is a schematic cross-sectional view showing a manufacturing step subsequent to the step shown in FIG. 11.

FIG. 13 is a schematic cross-sectional view showing a manufacturing step subsequent to the step shown in FIG. 12.

FIG. 14 is a schematic cross-sectional view of a nitride semiconductor device according to a comparative example.

FIG. 15 is an equipotential diagram showing a simulation result of electric field distribution of the nitride semiconductor device shown in FIG. 14.

FIG. 16 is a schematic cross-sectional view of are exemplary nitride semiconductor device including a first modified example of a gate layer.

FIG. 17 is a schematic cross-sectional view of an exemplary nitride semiconductor device including a second modified example of a gate layer.

FIG. 18 is a schematic cross-sectional view of an exemplary nitride semiconductor device including a third modified example of a gate layer.

Throughout the drawings and the detailed description, the same reference numerals refer to the same elements. The drawings may not be to scale, and the relative size, proportions, and depiction of elements in the drawings may be exaggerated for clarity, illustration, and convenience

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

Embodiments of a nitride semiconductor device according to the present disclosure will be described below with reference to the drawings.

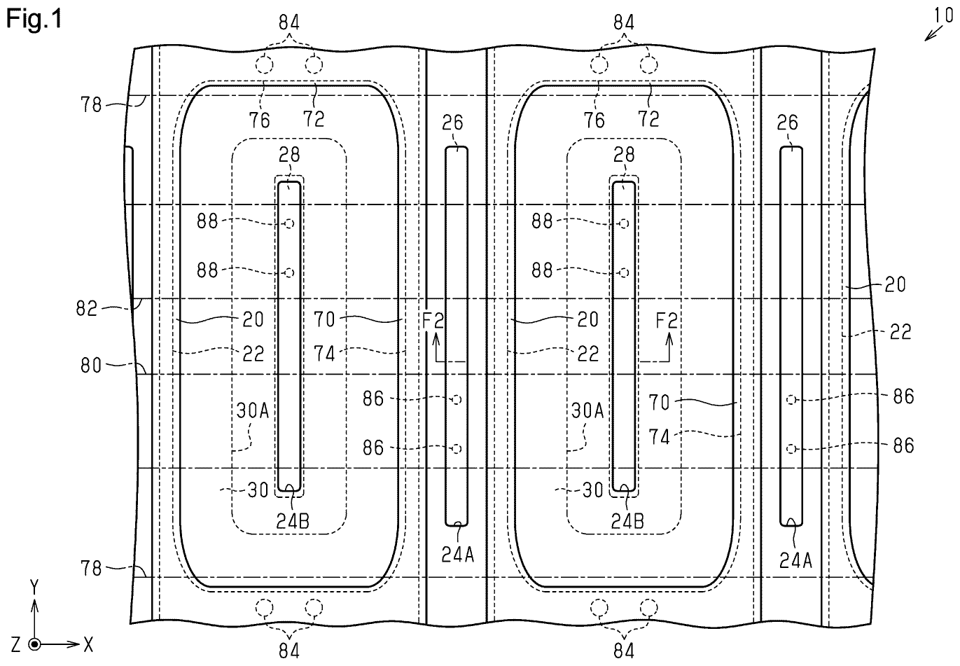

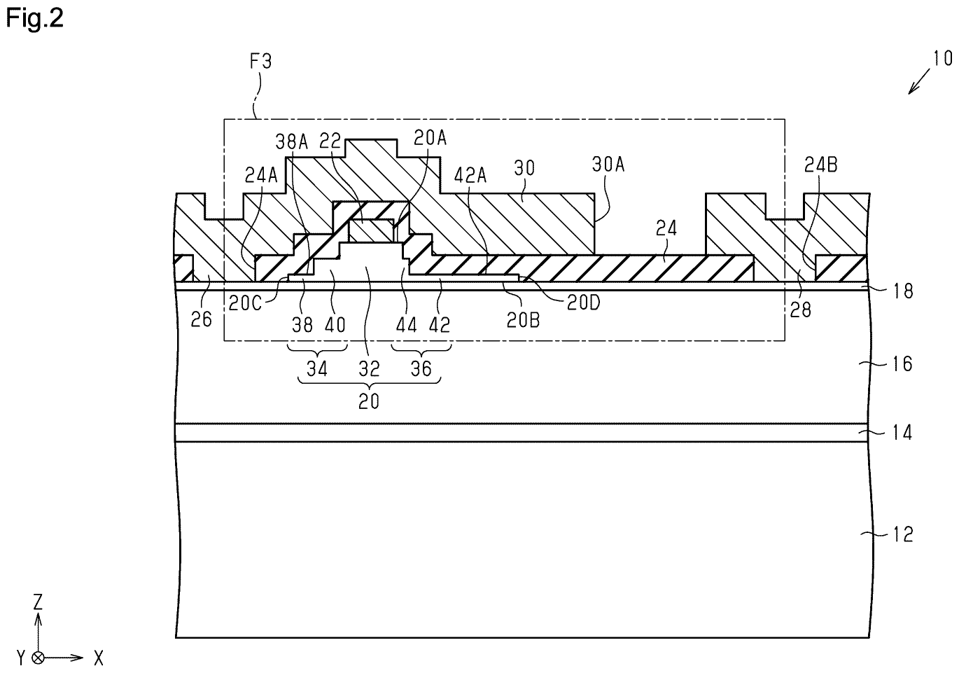

FIG. 1 is a schematic plan view showing an example of a nitride semiconductor device 10 in a first embodiment. FIG. 2 is a schematic cross-sectional view of the nitride semiconductor device 10 taken along line F2-F2 in FIG. 1. As shown in FIG. 2, the nitride semiconductor device 10 may include a semiconductor substrate 12 and a buffer layer 14 formed on the semiconductor substrate 12. Among XYZ-axes that are orthogonal to each other shown in FIGS. 1 and 2, a Z-axis direction is orthogonal to a surface of the semiconductor substrate 12. The term “plan view” used in this specification refers to a view of the nitride semiconductor device 10 in the Z-axis direction from above unless otherwise specifically described. The nitride semiconductor device 10 further includes an electron transit layer 16 and an electron supply layer 18 formed on the electron transit layer 16.

The semiconductor substrate 12 may be formed from silicon (Si), silicon carbide (SiC), GaN, sapphire, or other substrate materials. In an example, the semiconductor substrate 12 may be a Si substrate. The semiconductor substrate 12 may have a thickness that is, for example, greater than or equal to 200 μm and less than or equal to 1500 μm.

The buffer layer 14 may include one or more nitride semiconductor layers. The electron transit layer 16 may be formed on the buffer layer 14. The buffer layer 14 may be formed from any material that limits, for example, bending of the semiconductor substrate 12 caused by a mismatch in thermal expansion coefficient between the semiconductor substrate 12 and the electron transit layer 16 and formation of cracks in the nitride semiconductor device 10. In an example, the buffer layer 14 may include at least one of an aluminum nitride (AlN) layer, an aluminum gallium nitride (AlGaN) layer, and a graded AIGaN layer haying different aluminum (Al) compositions. For example, the buffer layer 14 may include a single AlN layer, a single AIGaN layer, a layer having a superlattice structure of AlGaN/GaN, a layer having a superlattice structure of AlN/AlGaN, or a layer having a superlattice structure of AlN/GaN.

In an example, the buffer layer 14 may include a first buffer layer that is an AlN layer formed on the semiconductor substrate 12 and a second buffer layer that is an AlGaN formed on the AlN layer. The first buffer layer may be, for example, an AlN layer having a thickness of 200 nm. The second buffer layer may be formed by stacking a graded AlGaN layer having a thickness of 300 nm a number of times. To inhibit current leakage of the buffer layer 14, a portion of the buffer layer 14 may be doped with an impurity so that the buffer layer 14 becomes semi-insulating. In this case, the impurity is, for example, carbon (C) or iron (Fe). The concentration of the impurity may be, for example, greater than or equal to 4×10¹⁶ cm⁻³.

The electron transit layer 16 is composed of a nitride semiconductor. The electron transit layer 16 may be, for example, a GaN layer. The electron transit layer 16 may have a thickness that is, for example, greater than or equal to 0.5 μm and less than or equal to 2 μm. To inhibit current leakage of the electron transit layer 16, a portion of the electron transit layer 16 may be doped with an impurity so that the electron transit layer 16 excluding an outer layer region becomes semi-insulating. In this case, the impurity may be, for example, C. The concentration of the impurity in the electron transit layer 16 may be, for example, greater than or equal to 4×10¹⁶ cm⁻³. More specifically, the electron transit layer 16 may include GaN layers having different impurity concentrations, for example, a C-doped GaN layer and a non-doped GaN layer. In this case, the C-doped GaN layer may be formed on the buffer layer 14. The C-doped GaN layer may have a thickness that is greater than or equal to 0.3 μm and less than or equal to 2 μm. The C concentration in the C-doped GaN layer may be greater than or equal to 5×10¹⁷ cm⁻³ and less than or equal to 9×10¹⁹ cm⁻³. The non-doped GaN layer may be formed on the C-doped GaN layer and may have a thickness that is greater than or equal to 0.05 μm and less than or equal to 0.4 μm. The non-doped GaN layer is in contact with the electron supply layer 18. In an example, the electron transit layer 16 may include a C-doped GaN layer having a thickness of 0.4 μm and a non-doped GaN layer having a thickness of 0.4 μm. The C concentration in the C-doped GaN layer may be approximately 2×10¹⁹ cm⁻³.

The electron supply layer 18 is composed of a nitride semiconductor having a band gap that is larger than that of the electron transit layer 16. The electron supply layer 18 may be, for example, an AlGaN layer. The band gap increases as the composition of Al increases. Therefore, the electron supply layer 18. which is an AlGaN layer, has a larger band gap than the electron transit layer 16, which is a GaN layer. In an example, the electron supply layer 18 is composed of AlₓGa₁₋ₓN, where 0.1<x<0.4, and more preferably, 0.1<x<0.3. The electron supply layer 18 may have a thickness that is greater than or equal to 5 nm and less than or equal to 20 nm. In an example, the electron supply layer 18 may have a thickness that is greater than or equal to 8 nm.

The electron transit layer 16 and the electron supply layer 18 are composed of nitride semiconductors having different lattice constants. Therefore, the nitride semiconductor forming the electron transit layer 16 (e.g., GaN) and the nitride semiconductor forming the electron supply layer 18 (e.g., AlGaN) form a lattice-mismatching heterojunction. The energy level of the conduction band of the electron transit layer 16 in the vicinity of the heterojunction interface is lower than the Fermi level due to spontaneous polarization of the electron transit layer 16 and the electron supply layer 18 and piezoelectric polarization caused by crystal distortion in the vicinity of the heterojunction interface. As a result, at a location close to the heterojunction interface between the electron transit layer 16 and the electron supply layer 18 (e.g., within range approximately a few nanometers from the interface), two-dimensional electron gas (2DEG) spreads in the electron transit layer 16. The sheet carrier density of the 2DEG formed in the electron transit layer 16 may be increased by increasing at least one of the Al composition and the thickness of the electron supply layer 18.

Gate Layer and Gate Electrode

The nitride semiconductor device 10 further includes a gate layer 20 formed on the electron supply layer 18 and a gate electrode 22 formed on the gate layer 20. The gate layer may be formed on a portion of the electron supply layer 18.

The gate layer 20 is composed of a nitride semiconductor containing an acceptor impurity. In the present embodiment, the gate layer 20 may be a gallium nitride layer (p-type GaN layer) doped with an acceptor impurity. The acceptor impurity may include at least one of zinc (Zn), magnesium (Mg), and carbon (C). The maximum concentration of the acceptor impurity in the gate layer 20 may be greater than or equal to 7×10¹⁸ cm⁻³ and less than or equal to 1×10²⁰ cm⁻³. In an example, the gate layer 20 may be GaN containing at least one of Mg and Zn as an impurity. Further details of the gate layer 20 will be described later.

The gate electrode 22 may be composed of one or n more metal layers. In an example, the gate electrode 22 may be composed of a titanium nitride (TiN) layer. In another example, the gate electrode 22 may be composed of a first metal layer formed from Ti and a second metal layer formed from TiN and disposed on the first metal layer. The gate electrode 22 may form a Schottky junction with the gate layer 20. The gate electrode 22 may be formed in a region smaller than the gate layer 20 in plan view. The gate electrode 22 may have a thickness that is, for example, greater than or equal to 50 nm and less than or equal to 200 nm.

The nitride semiconductor device 10 further includes a passivation layer 24 that covers the electron supply layer 18, the gate layer 20, and the gate electrode 22. The passivation layer 24 includes a first opening 24A and a second opening 24B that are separated from each other in an X-axis direction. In this specification, the X-axis direction is also referred to as a first direction, and a Y-axis direction is also referred to as a second direction. Hence, the second direction is orthogonal to the first direction in plan view. The gate layer 20 is disposed between the first opening 24A and the second opening 24B. More specifically, the gate layer 20 may be disposed between the first opening 24A and the second opening 24B at a position closer to the first opening 24A than to the second opening 24B. The passivation layer 24 may be formed from, for example, at least one of silicon nitride (SiN), silicon dioxide (SiO₂), silicon oxynitride (SiON), alumina (Al₂O₃), AlN, and aluminum oxynitride (AION). The passivation layer 24 may have a thickness that is, for example, greater than or equal to 80 nm and less than or equal to 150 nm.

Source Electrode and Drain Electrode

The nitride semiconductor device 10 further includes a source electrode 26. which is in contact with the electron supply layer 18 through the first opening 24A, and a drain electrode 28, which is in contact with the electron supply layer 18 through the second opening 24B. The source electrode 26 and the drain electrode 28 may be composed of one or more metal layers (e.g., any combination of a Ti layer, a TiN layer, an Al layer, an AlSiCu layer, an AlCu layer, and the like).

At least a portion of the source electrode 26 fills the first opening 24A. This allows the source electrode 26 to be in ohmic contact with the 2DEG, which is located immediately below the electron supply layer 18, through the first opening 24A. Also, at least a portion of the drain electrode 28 fills the second opening 24B. This allows the drain electrode 28 to be in ohmic contact with the 2DEG, which is located immediately below the electron supply layer 18, through the second opening 24B.

Field Plate Electrode

The nitride semiconductor device 10 may optionally further include a field plate electrode 30 formed on the passivation layer 24. The field plate electrode 30 is electrically connected to the source electrode 26. As shown in FIG. 2, the field plate electrode 30 may be continuous with the source electrode 26. In this case, the field plate electrode 30 is formed integrally with the source electrode 26. Of the integrally formed electrodes, the source electrode 26 may include at least the portion that is embedded in the first opening 24A of the passivation layer 24, and the field plate electrode 30 may include the remaining portion.

The field plate electrode 30 is separated from the drain electrode 28. Therefore, the field plate electrode 30 may include an end 30A located between the drain electrode 28 (second opening 24B) and the gate layer 20 in plan view.

When a drain voltage is applied to the drain electrode 28 in the zero bias state, in which no gate voltage is applied to the gate electrode 22, the field plate electrode 30 reduces concentration of electric field in the vicinity of an end of the gate electrode 22.

Planar Layout of Nitride Semiconductor Device

An example of the planar layout of the nitride semiconductor device 10 will be described with reference to FIG. 1. In FIG. 1, the gate electrode 22, the source electrode 26, the drain electrode 28, and the field plate electrode 30 are indicated by broken lines. The first opening 24A and the second opening 24B are indicated by solid lines, while the remaining of the passivation layer 24 is transparently shown.

As shown in FIG. 1, the gate layer 20 may be formed to surround the drain electrode 28 in plan view. The gate layer 20 may include body portions 70 extending in the Y-axis direction and connection portions 72 connecting adjacent ones of the body portions The body portion 70 of the gate layer 20 is disposed between the first opening 24A and the second opening 24B of the passivation layer 24.

In plan view, the gate electrode 22 is disposed to overlap the gate layer 20. Thus, in the same manner as the gate layer 20, the gate electrode 22 may be formed to surround the drain electrode 28 in plan view. The gate layer 22 may include body portions 74 extending in the Y-axis direction and connection portions 76 connecting adjacent ones of the body portions 74. The gate electrode 22 may be smaller in area in plan view than the gate layer 20.

The nitride semiconductor device 10 may include a gate interconnect 78, a source interconnect 80, and a drain interconnect 82. In FIG. 1, the gate interconnect 78, the source interconnect 80, and the drain interconnect 82 are indicated by single-dashed lines. The gate interconnect 78, the source interconnect 80, and the drain interconnect 82 are located above the source electrode 26 and the drain electrode 28 in the Z-axis direction. The gate interconnect 78 may extend in the X-axis direction and be disposed above the connection portion 76 of the gate electrode 22. The source interconnect 80 and the drain interconnect 82 may extend in the X-axis direction and respectively intersect with the source electrode 26 and the drain electrode 28 in plan view. In an example, the gate electrode 22 may be electrically connected to the gate interconnect 78 through vias 84 disposed on the connection portion 76. The source electrode 26 may be electrically connected to the source interconnect 80 through vias 86. The drain electrode 28 may be electrically connected to the drain interconnect 82 through vias 88.

The planar layout of the nitride semiconductor device 10 is not limited to the example shown in FIG. 1. Any other planar layout may be applied to the nitride semiconductor device 10.

Detail of Gate Layer

Referring again to FIG. 2, the gate layer 20 may include an upper surface 20A on which the gate electrode 22 is formed and a bottom surface 20B that is in contact with the electron supply layer 18. The gate layer 20 includes a ridge 32 including the upper surface on which the gate electrode 22 is formed, and a source-side extension 34 and a drain-side extension 36 that are smaller in thickness than the ridge 32. Each of the ridge 32, the source-side extension 34, and the drain-side extension 36 is in contact with the electron supply layer 18. The source-side extension 34 and the drain-side extension 36 extend outward from the ridge 32 in plan view. The source-side extension 34 and the drain-side extension 36 are not shown in FIG. 1.

The source-side extension 34 extends from the ridge 32 toward the first opening 24A. The source-side extension 34 does not reach the first opening 24A. The passivation layer 24 is disposed between the source-side extension 34 and the source electrode 26, which is embedded in the first opening 24A.

The drain-side extension 36 extends from the ridge 32 toward the second opening 24B. The drain-side extension 36 does not reach the second opening 24B. The passivation layer 24 is disposed between the drain-side extension 36 and the drain electrode 28, which is embedded in the second opening 24B.

The ridge 32 is disposed between the source-side extension 34 and the drain-side extension 36 and is formed integrally with the source-side extension 34 and the drain-side extension 36, Since the gate layer 20 includes the source-side extension 34 and the drain-side extension 36, the bottom surface 20B is greater in area than the upper surface 20A. In the example shown in FIG. 2, the drain-side extension 36 may extend outward from the ridge 32 longer than the source-side extension 34 in plan view. In other words, the drain-side extension 36 may be greater in dimension in the X-axis direction than the source-side extension 34. The source-side extension 34 may have a dimension in the X-axis direction that is greater than or equal to 0.05 μm and less than or equal to 0.3 μm. More preferably, the dimension of the source-side extension 34 in the X-axis direction may be, for example, greater than or equal to 0.2 μm and less than or equal to 0.3 μm. The drain-side extension 36 may have a dimension in the X-axis direction that is greater than or equal to 0.05 μm and less than or equal to 0.6 μm. More preferably, the dimension of the drain-side extension 36 in the X-axis direction may be, for example, greater than or equal to 0.2 μm and less than or equal to 0.6 μm.

The ridge 32 corresponds to a relatively thick portion of the gate layer 20. The ridge 32 may have a thickness that is greater than or equal to 50 nm and less than or equal to 200 nm. More preferably, the thickness of the ridge 32 may be, for example, greater than or equal to 80 nm and less than or equal to 150 nm. The thickness of the ridge 32 may be determined taking into consideration parameters including the gate threshold voltage. In an example, the thickness of the ridge 32 may be greater than 110 nm.

The source-side extension 34 includes a first step portion 38 including an upper surface 38A parallel to the bottom surface 20B of the gate layer 20 and a first intermediate portion 40 connecting the first step portion 38 to the ridge 32. The drain-side extension 36 includes a second step portion 42 including an upper surface 42A parallel to the bottom surface 20B of the gate layer 20 and a second intermediate portion 44 connecting the second step portion 42 to the ridge 32. In this specification, “first surface being parallel to second surface” means that the angle formed by a normal line of the first surface and a normal line of the second surface is within 10 degrees. The first step portion 38 includes a first end 20C of the gate layer 20 located toward the first opening 24A The second step portion 42 includes a second end 20D of the gate layer 20 located toward the second opening 24B. The first end 20C and the second end 20D are ends of the gate layer 20 in the X-axis direction.

The first step portion 38 may have a substantially constant thickness, In this specification, “substantially constant thickness” means that the thickness is within a. manufacturing variation range (for example, 20%). In an example, the first step portion 38 may have a thickness that is greater than or equal to 5 nm and less than or equal to 25 nm. More preferably, the thickness of the first step portion 38 may be greater than or equal to 15 nm and less than or equal to 20 nm. The first intermediate portion 40 may have a thickness that is greater than or equal to the thickness of the first step portion 38 and less than the thickness of the ridge 32.

The second step portion 42 may have a substantially constant thickness. In an example, the second step portion 42 may have a thickness that is greater than or equal to 5 nm and less than or equal to 25 nm. More preferably, the thicknesses of the second step portion 42 may be greater than or equal to 15 nm and less than or equal to 20 nm. The second intermediate portion 44 may have a thickness that is greater than or equal to the thickness of the second step portion 42 and less than the thickness of the ridge 32. The second step portion 42 and the first step portion 38 may be equal in thickness.

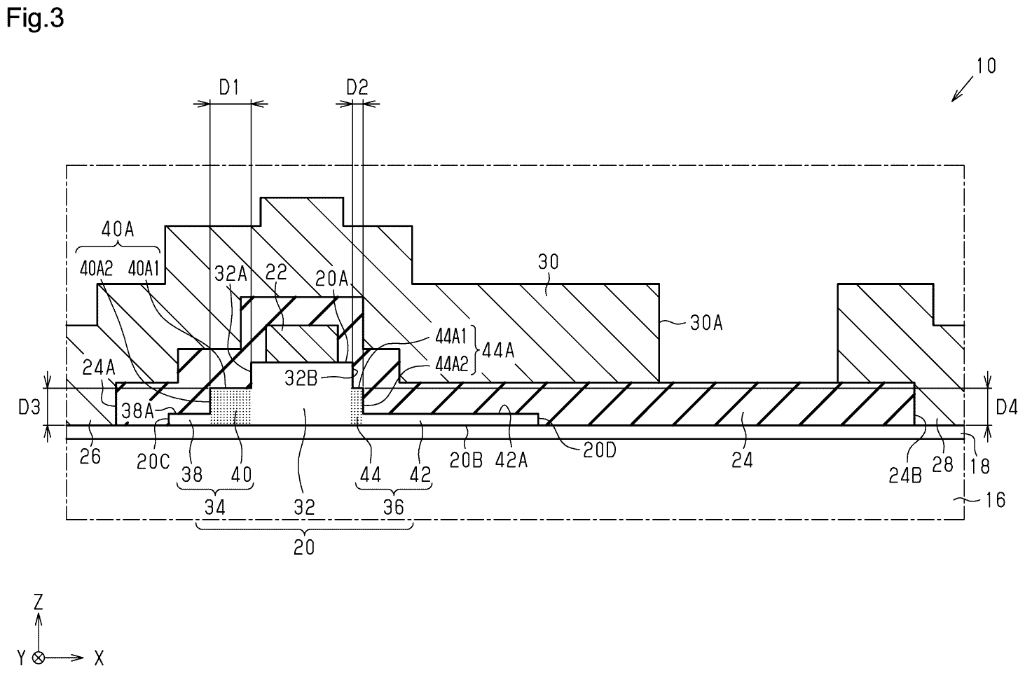

FIG. 3 is an enlarged view of the portion shown in FIG. 2 surrounded by the single-dashed line F3 for further describing the gate layer 20. The ridge 32 includes a first side surface 32A and a second side surface 32B opposite to the first side surface 32A. The first side surface 32A and the second side surface 32B may be flat. The first side surface 32A and the second side surface 32B intersect with the X-axis direction. The first side surface 32A and the second side surface 32B may be orthogonal to the X-axis direction or may intersect with the X-axis direction at an angle other than right angles.

The first intermediate portion 40 includes a first intermediate surface 40A connecting the first side surface 32A of the ridge 32 and the upper surface 38A of the first step portion 38. The second intermediate portion 44 includes a second intermediate surface 44A connecting the second side surface 32B of the ridge 32 and the upper surface 42A of the second step portion 42.

In the example of FIG. 3, the first intermediate surface 40A may include one step. More specifically, the first intermediate surface 40A may include an upper surface 40A1. and a side surface 40A2 of the first intermediate portion 40. The upper surface 40A1 of the first intermediate portion 40 may be parallel to the upper surface 38A of the first step portion 38. The side surface 40A2 of the first intermediate portion 40 connects the upper surface 40A1 of the first intermediate portion 40 and the upper surface 38A of the first step portion 38. The side surface 40A2 of the first intermediate portion 40 may extend vertically or obliquely between the upper surface 40A1 of the first intermediate portion 40 and the upper surface 38A of the first step portion 38. The upper surface 40A1 of the first intermediate portion 40 is disposed between the upper surface 20A of the gate layer 20 and the upper surface 38A of the first step portion 38 in the Z-axis direction.

In the same manner, the second intermediate surface 44A may include one step. More specifically, the second intermediate surface 44A may include an upper surface 44A1 and a side surface 44A2 of the second intermediate portion 44. The upper surface 44A1 of the second intermediate portion 44 may be parallel to the upper surface 42A of the second step portion 42. The side surface 44A2 of the second intermediate portion 44 connects the upper surface 44A1 of the second intermediate portion 44 and the upper surface 42A of the second step portion 42. The side surface 44A2 of the second intermediate portion 44 may extend vertically or obliquely between the upper surface 44A1 of the second intermediate portion 44 and the upper surface 42A of the second step portion 42, The upper surface 44A1 of the second intermediate portion 44 is disposed between the upper surface 20A of the gate layer 20 and the upper surface 42A of the second step portion 42 in the Z-axis direction.

The first intermediate portion 40 has a cross-sectional area that is greater than that of the second intermediate portion 44 in a plane orthogonal to the Y-axis direction. The cross-sectional area of the first intermediate portion 40 corresponds to the area of a region (in FIG. 3, dot pattern region) between the first intermediate surface 40A and the bottom surface 20B of the gate layer 20. The cross-sectional area of the second intermediate portion 44 corresponds to the area of a region (in FIG. 3, dot pattern region) between the second intermediate surface 44A and the bottom surface 20B of the gate layer 20.

In the example of FIG. 3, a dimension D1 of the first intermediate portion 40 in the X-axis direction may be larger than a dimension D2 of the second intermediate portion 44 in the X-axis direction. in an example, the dimension D1 of the first intermediate portion 40 may be greater than or equal to 5 nm and less than or equal to 100 nm in the X-axis direction. The dimension D2 of the second intermediate portion 44 may be greater than or equal to 5 nm and less than or equal to 100 nm in the X-axis direction. A dimension D3 of the first intermediate portion 40 in the Z-axis direction may be equal to a dimension D4 of the second intermediate portion 44 in the Z-axis direction. The dimension D3 of the first intermediate portion 40 in the Z-axis direction may be the thickness of the thickest part of the first intermediate portion 40. The dimension D4 of the second intermediate portion 44 in the Z-axis direction may be the thickness of the thickest part of the second intermediate portion 44. In an example, the thicknesses of each of the first intermediate portion 40 and the second intermediate portion 44 may be in a range from 10 nm to 80 nm. The dimension

D3 of the first intermediate portion 40 in the Z-axis direction may be the thickness of the first intermediate portion 40 at a position adjacent to the ridge 32. The dimension D4 of the second intermediate portion 44 in the Z-axis direction may be the thickness of the second intermediate portion 44 at a position adjacent to the ridge 32. In this specification, the dimension D3 of the first intermediate portion 40 in the Z-axis direction may be simply referred to as the thickness of the first intermediate portion 40. The dimension D4 of the second intermediate portion 44 in the Z-axis direction may be simply referred to as the thickness of the second intermediate portion 44.

In another example, the dimension D1 may be smaller than or equal to the dimension D2. In this case, the dimension D3 may be set to be larger than the dimension D4 so that the cross-sectional area of the first intermediate portion 40 is greater than the cross-sectional area of the second intermediate portion 44.

Method for Manufacturing Nitride Semiconductor Device

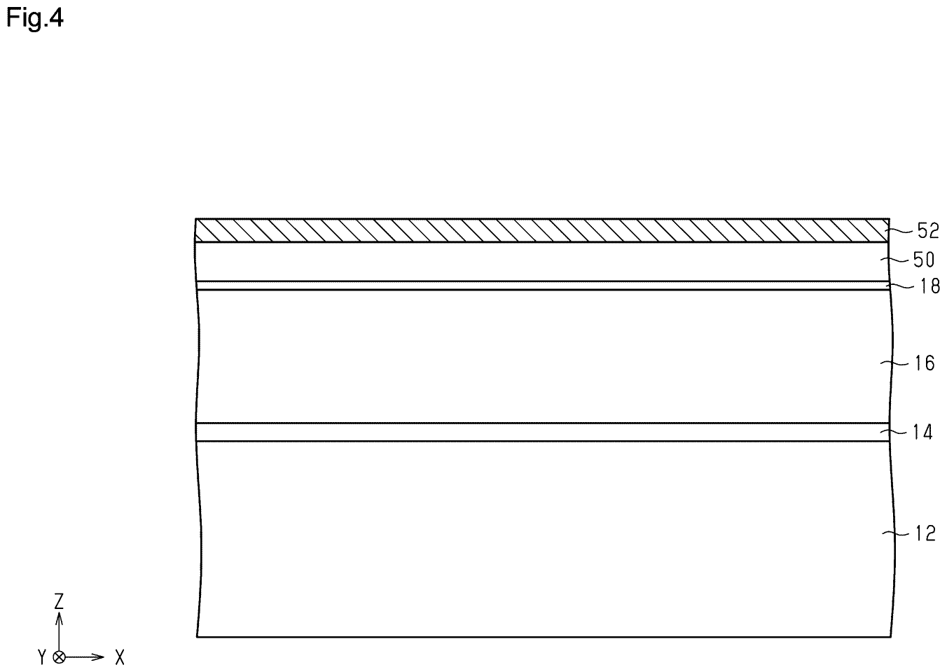

An example of a method for manufacturing the nitride semiconductor device 10 shown in FIG. 2 will be described. FIGS. 4 to 13 are schematic cross-sectional views showing exemplary manufacturing steps of the nitride semiconductor device 10. To facilitate understanding, in FIGS. 4 to 13, the same reference characters are given to those components that are the same as the corresponding components shown in FIG. 2.

As shown FIG. 4, the method for manufacturing the nitride semiconductor device includes sequentially forming the buffer layer 14, the electron transit layer 16, the electron supply layer 18, a gallium nitride (GaN) layer 50, and a metal layer 52 on the semiconductor substrate 12, which is, for example, a Si substrate. Metal organic chemical vapor deposition (MOCVD) may be used to epitaxially grow the buffer layer 14, the electron transit layer 16, the electron supply layer 18, and the GaN layer 50. The metal layer 52 may be formed by, for example, sputtering.

Although not shown in detail, in an example, the buffer layer 14 may be a multilayer buffer layer. The multilayer buffer layer may include an AlN layer (first buffer layer) formed on the semiconductor substrate 12 and a graded AlGaN layer (second buffer layer) formed on the AlN layer. The graded AIGaN layer may be formed, for example, by stacking three AlGaN layers haying Al compositions of 75%, 50%, and 25% in the order from the side of the MN layer.

The electron transit layer 16 formed on the buffer layer 14 may be a GaN layer. The electron supply layer 18 formed on the electron transit layer 16 may be an AlGaN layer. Therefore, the electron supply layer 18 is composed of a nitride semiconductor having a band gap that is larger than that of the electron transit layer 16.

The GaN layer 50 formed on the electron supply layer 18 may contain magnesium as an acceptor impurity. The GaN layer 50 that contains an acceptor impurity may be formed by doping the GaN layer 50 with magnesium while the GaN layer 50 is growing on the electron supply layer 18. The amount of magnesium, as a dopant in the GaN layer 50, may be adjusted by controlling, for example, the growth temperature and the flow rate of a doping gas (e.g., biscyclopentadienyl magnesium (Cp₂Mg)) supplied to the growth chamber. In an example, the GaN layer 50 may contain magnesium as an impurity at a concentration that is greater than or equal to 1×10¹⁸ cm⁻³ and less than 1×10²⁰ cm⁻³.

The metal layer 52 may be formed on the GaN layer 50 by, for example, sputtering. In an example, the metal layer 52 may be a TiN layer.

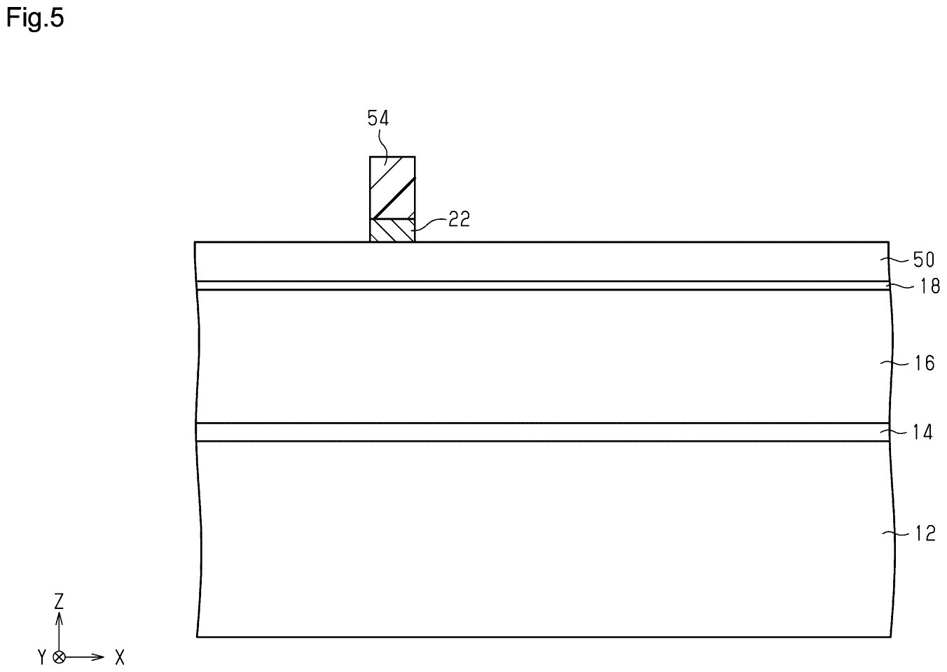

FIG. 5 is a schematic cross-sectional view showing a manufacturing step subsequent to the step shown in FIG. 4. As shown in FIG. 5, the method for manufacturing the nitride semiconductor device 10 further includes selectively removing the metal layer 52 (refer to FIG. 4) by lithography and etching to form the gate electrode 22. In this step, a mask 54 is formed on a portion of the metal layer 52 that will become the gate electrode 22.

The mask 54 may be formed by, for example, exposing a photoresist that is applied to the metal layer 52. In another example, the mask 54 may be a hard mask. The metal layer 52 is etched using the mask 54 to remove the portion of the metal layer 52 that is not covered by the mask 54. As a result, the portion of the metal layer 52 covered by the mask 54 remains to from the gate electrode 22. The mask 54 is removed after the etching,

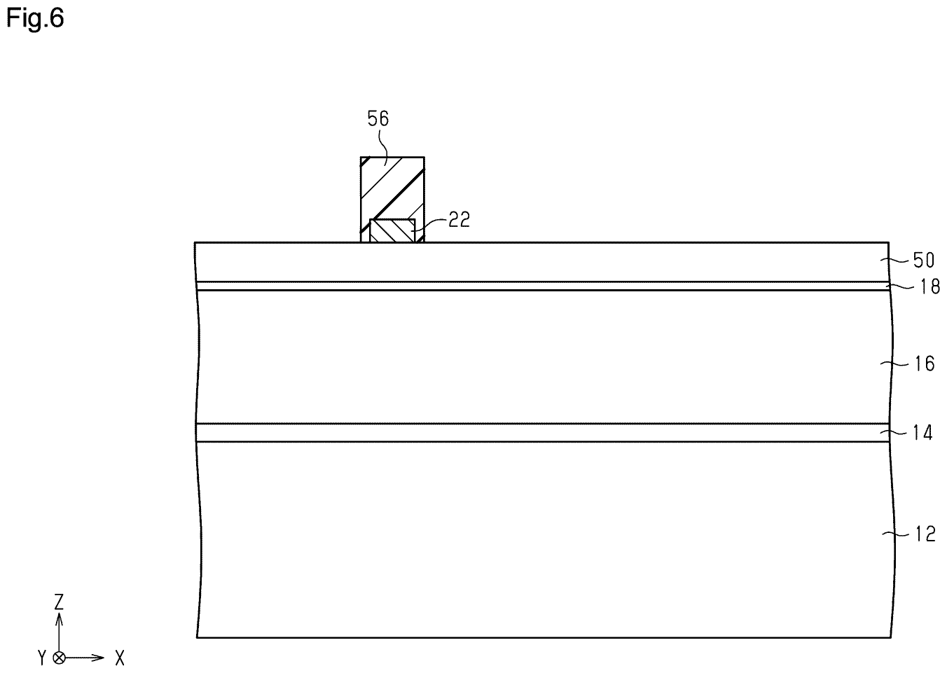

FIG. 6 is a schematic cross-sectional view showing a manufacturing step subsequent to the step shown in FIG. 5. As shown in FIG. 6, the method of manufacturing the nitride semiconductor device 10 further includes forming a mask 56 that covers the upper surface and the side surface of the gate electrode 22 and a region of the GaN layer 50 around the gate electrode 22. The region of the GaN layer 50 around the gate electrode 22 covered by the mask 56 extends symmetrically about the gate electrode 22 in the X-axis direction. In other words, the mask 56 is formed such that the center of the mask 56 is aligned with the center of the gate electrode 22 in the X-axis direction. The mask 56 may be a resist mask.

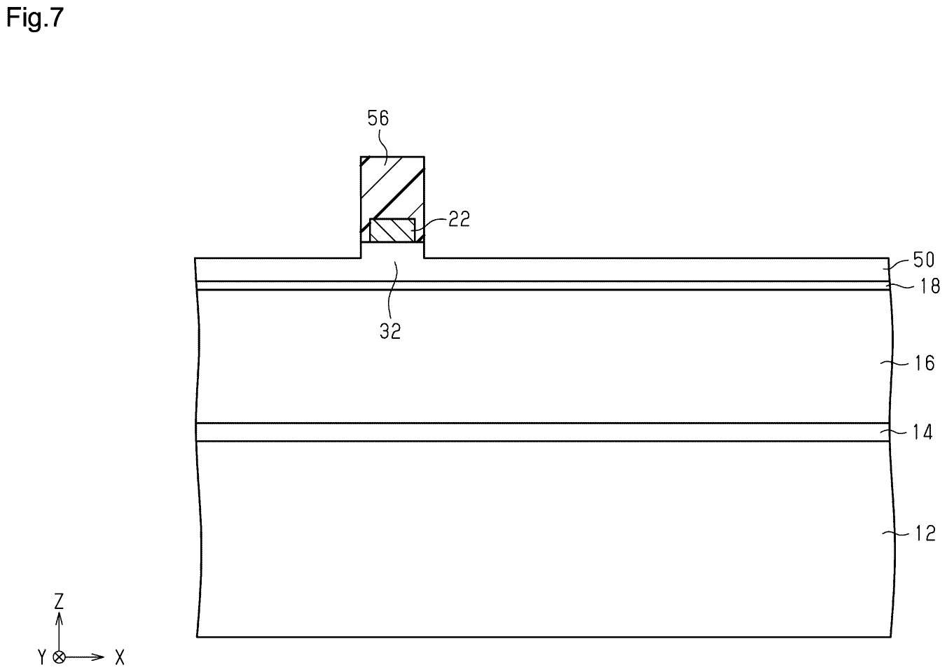

FIG. 7 is a schematic cross-sectional view showing a manufacturing step subsequent to the step shown in FIG. 6. As shown in FIG. 7, the method of manufacturing the nitride semiconductor device 10 further includes etching the GaN layer 50 using the mask 56. As a result of etching, the GaN layer 50 remains under the mask 56 to form the ridge 32, which has been described with reference to FIG. 2. The etching decreases the thickness of the GaN layer 50 that is not covered by the mask 56. For example, a portion of the GaN layer 50 corresponding to one third of the thickness may be removed by etching. The mask 56 is removed after the etching.

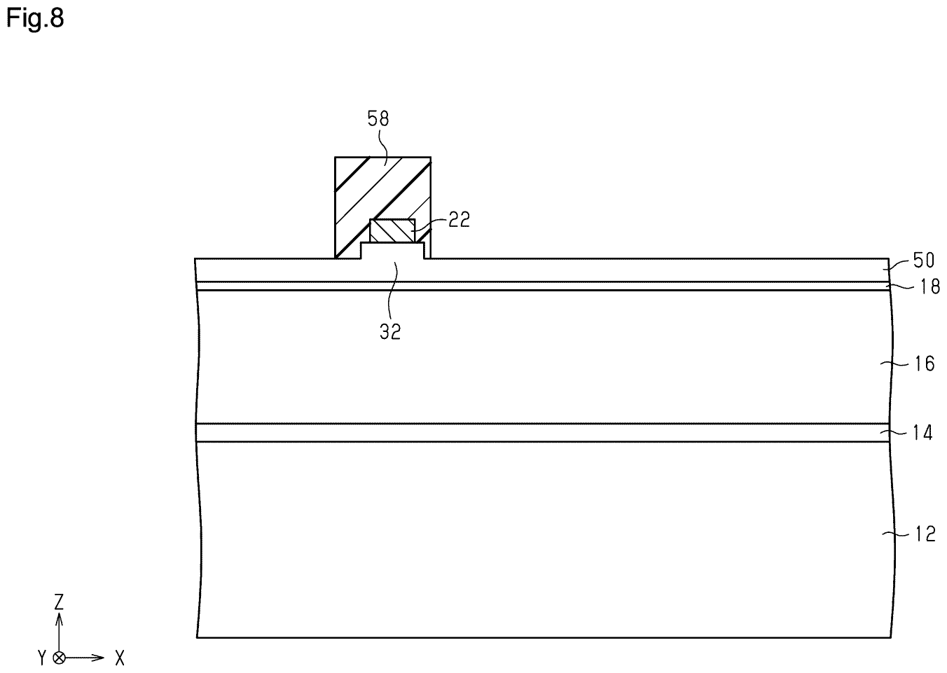

FIG. 8 is a schematic cross-sectional view showing a manufacturing step subsequent to the step shown in FIG. 7. As shown in FIG. 8, the method of manufacturing the nitride semiconductor device 10 further includes forming a mask 58 that covers the upper surface and the side surface of the gate electrode 22, the ridge 32, and a region of the GaN layer 50 around the ridge 32. The region of the GaN layer 50 around the ridge 32 covered by the mask 58 extends asymmetrically about the ridge 32 in the X-axis direction. In other words, the mask 58 is formed such that the center of the mask 58 is not aligned with the center of the ridge 32 (the center of the gate electrode 22) in the X-axis direction.

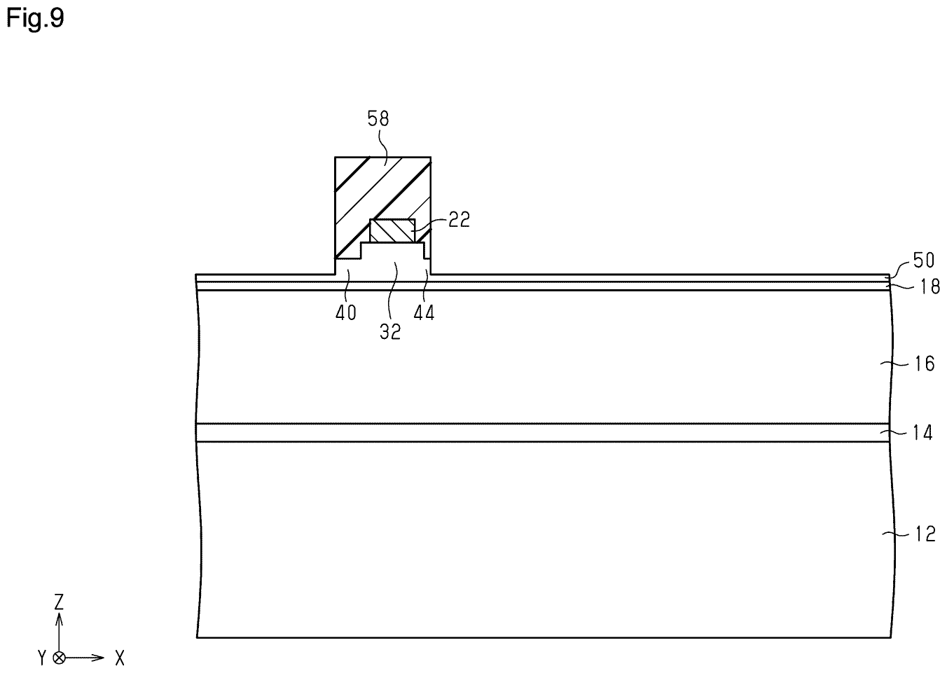

FIG. 9 is a schematic cross-sectional view showing a manufacturing step subsequent to the step shown in FIG. 8. As shown in FIG. 9, the method of manufacturing the nitride semiconductor device 10 further includes etching the GaN layer 50 using the mask 58. As a result of etching, the GaN layer 50 (including the ridge 32) remains under the mask 58 to form the first intermediate portion 40 and the second intermediate portion 44, which have been described with reference to FIG. 2. The etching decreases the thickness of the GaN layer 50 that is not covered by the mask 58. The portion of the GaN layer 50 that is not covered by the mask 58 is etched to have a thickness corresponding to the thickness of the first step portion 38 and the second step portion 42 shown in FIG. 2. The mask 58 is removed after the etching.

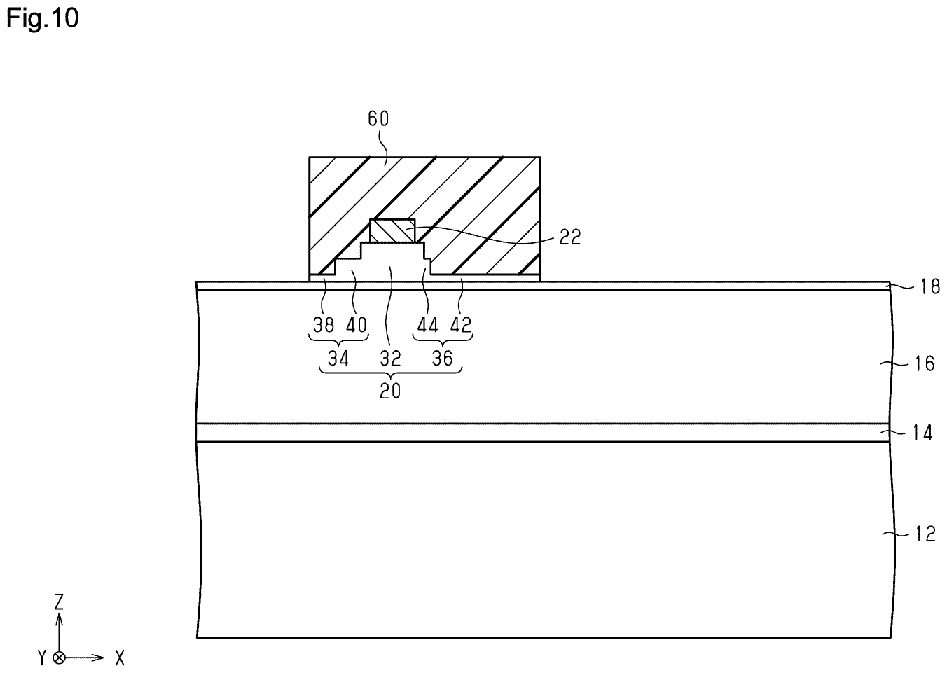

FIG. 10 is a schematic cross-sectional view showing a manufacturing step subsequent to the step shown in FIG. 9. As shown in FIG. 10, the method of manufacturing the nitride semiconductor device 10 further includes selectively removing the GaN layer 50 (refer to FIG. 9) by lithography and etching to form the first step portion 38 and the second step portion 42. In this step, the mask 60 is formed to cover the gate electrode 22, the ridge 32, the first intermediate portion 40 and the second intermediate portion 44, and portions of the GaN layer 50 corresponding to the first step portion 38 and the second step portion 42. The GaN layer 50 is patterned using the mask 60. As a result, the gate layer 20 including the ridge 32, the source-side extension 34 (the first step portion 38 and the first intermediate portion 40), and the drain-side extension 36 (the second step portion 42 and the second intermediate portion 44) are formed on the electron supply layer 18. The mask 60 is removed after the etching.

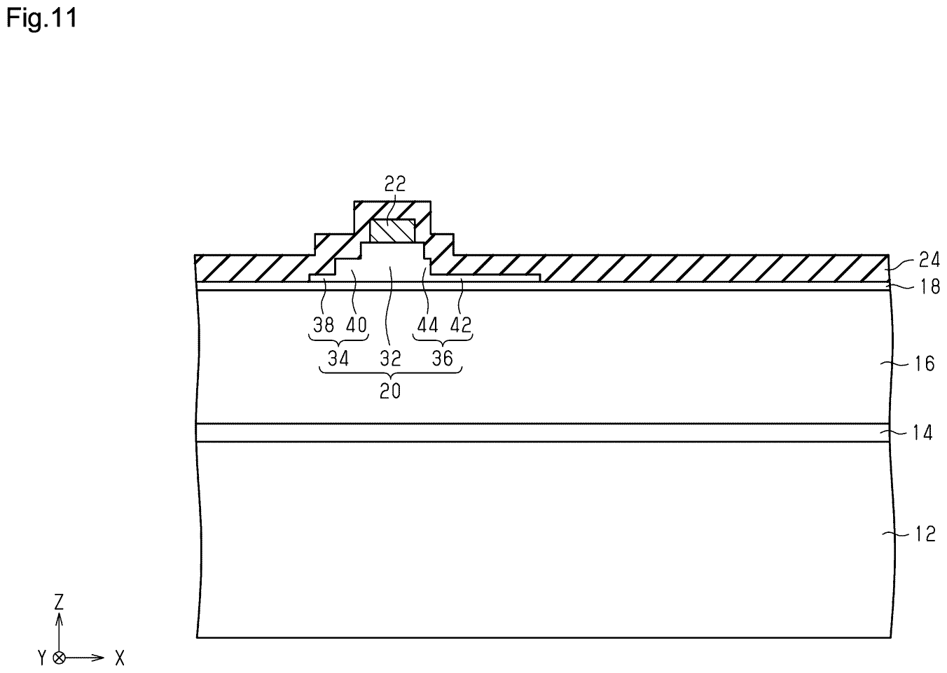

FIG. 11 is a schematic cross-sectional view showing a manufacturing step subsequent to the step shown in FIG. 10. As shown in FIG. 11, the method for manufacturing the nitride semiconductor device 10 further includes forming the passivation layer 24 to cover the entirety of exposed surfaces of the electron supply layer 18, the gate layer 20, and the gate electrode 22. In an example, the passivation layer 24 may be a Silt layer formed by low-pressure chemical vapor deposition (LPCVD).

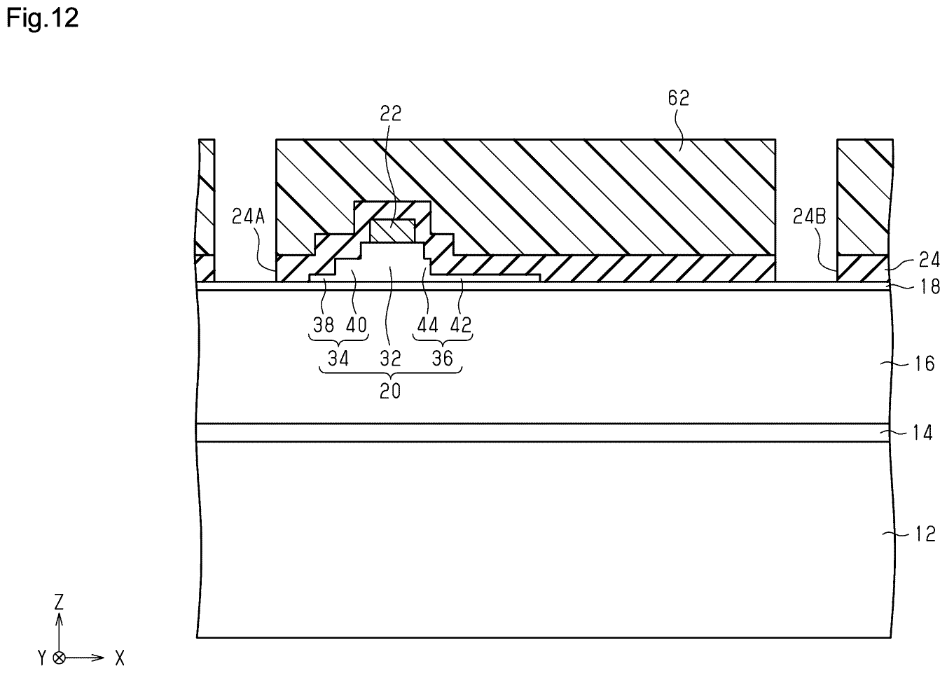

FIG. 12 is a schematic cross-sectional view showing a manufacturing step subsequent to the step shown in FIG. 11. As shown in FIG. 12, the method for manufacturing the nitride semiconductor device 10 further includes selectively removing the passivation layer 24 by lithography and etching to form the first opening 24A and the second opening 24B. In this step, a mask 62 is formed to cover the passivation layer 24 except for regions in which the first opening 24A and the second opening 2413 will be formed. Then, the passivation layer 24 is patterned using the mask 62. This forms the first opening 24A and, the second opening 24B extending through the passivation layer 24 and exposing the electron supply layer 18. The first opening 24A and the second opening 2413 are formed such that the gate layer 20 is located between the first opening 24A and the second opening 24B, The gate layer 20 may be located closer to the first opening 24A than to the second opening 24B. The mask 62 is removed after the etching.

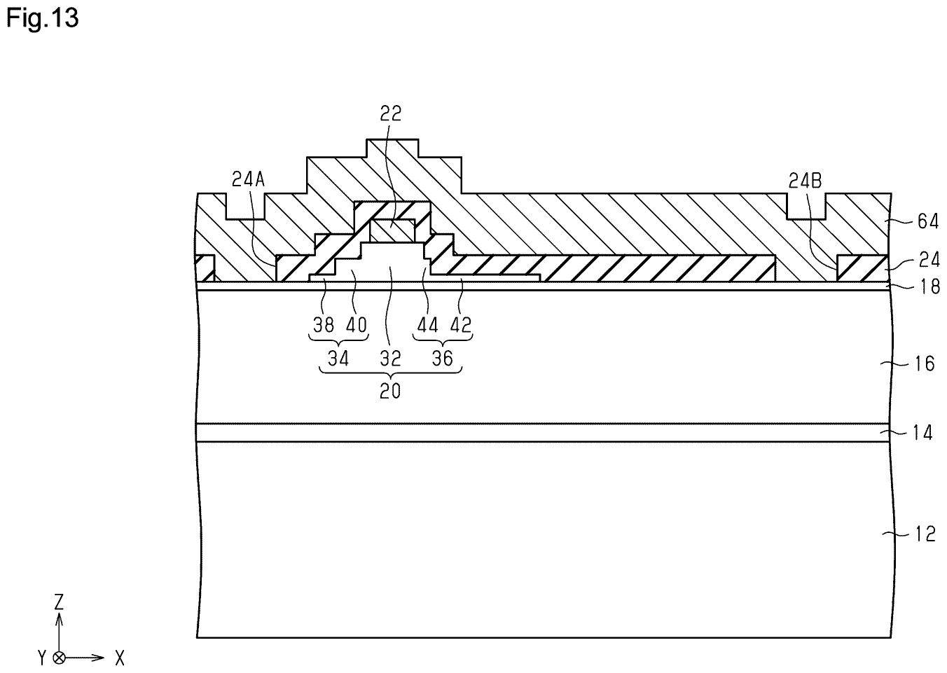

FIG. 13 is a schematic cross-sectional view showing a manufacturing step subsequent to the step shown in FIG. 12. As shown in FIG. 13, the method for manufacturing the nitride semiconductor device 10 further includes forming a metal layer 64 covering the passivation layer 24. The metal layer 64 is formed to fill the first opening 24A and the second opening 24B and contact the electron supply layer 18 through the first opening 24A and the second opening 24B. In an example, the metal layer 64 may include at least one of a Ti layer, a TiN layer, an Al layer, an AlSiCu layer, and an AlCu layer.

The metal layer 64 is selectively removed by lithography and etching to form the source electrode 26, the drain electrode 28, and the field plate electrode 30 shown in FIG. 2. This obtains the nitride semiconductor device 10 shown in FIG. 2.

Operation of Nitride Semiconductor Device

The operation of the nitride semiconductor device 10 of the present embodiment will be described below. When a voltage exceeding the threshold voltage is applied to the gate electrode 22 of the nitride semiconductor device 10, a channel of the 2DEG is formed in the electron transit layer 16 and establishes a source-drain connection. In contrast, in the zero bias state, the 2DEG is not formed in at least a portion of the region of the electron transit layer 16 located under the gate layer 20. This is because the acceptor impurity contained in the gate layer 20 raises the energy levels of the electron transit layer 16 and the electron supply layer 18. As a result, the 2DEG is depleted. This achieves the normally-off operation of the nitride semiconductor device 10.

The gate layer 20 includes the source-side extension 34 and the drain-side extension 36 that are smaller in thickness than the ridge 32. When a voltage is applied to the gate electrode 22, equipotential lines in the ridge 32 partially extend through the source-side extension 34 and the drain-side extension 36. This limits local concentration of electric field in the vicinity of ends of the ridge 32 (e.g., in the electron supply layer 18), which may occur when the source-side extension 34 and the drain-side extension 36 are not arranged.

When the source-side extension 34 and the drain-side extension 36 are relatively thick, the on-resistance of the nitride semiconductor device 10 is increased. Therefore, the first step portion 38 of the source-side extension 34 and the second step portion 42 of the drain-side extension 36 may have any thickness (for example, 20 nm or less) that obtains a desired value of on-resistance while increasing the breakdown voltage of the nitride semiconductor device 10. The source-side extension 34 and the drain-side extension 36, which are smaller in thickness than the ridge 32, may have a higher density of the equipotential lines than the ridge 32. In this regard, the source-side extension 34 includes the first intermediate portion 40 connecting the first step portion 38 to the ridge 32 to reduce the density of the equipotential lines in the source-side extension 34. The first intermediate portion 40 may have a thickness that is greater than or equal to the thickness of the first step portion 38 and less than the thickness of the ridge 32. Also, the drain-side extension 36 includes the second intermediate portion 44 connecting the second step portion 42 to the ridge 32 to reduce the density of equipotential lines in the drain-side extension 36. The second intermediate portion 44 may have a thickness that is greater than or equal to the thickness of the second step portion 42 and less than the thickness of the ridge 32.

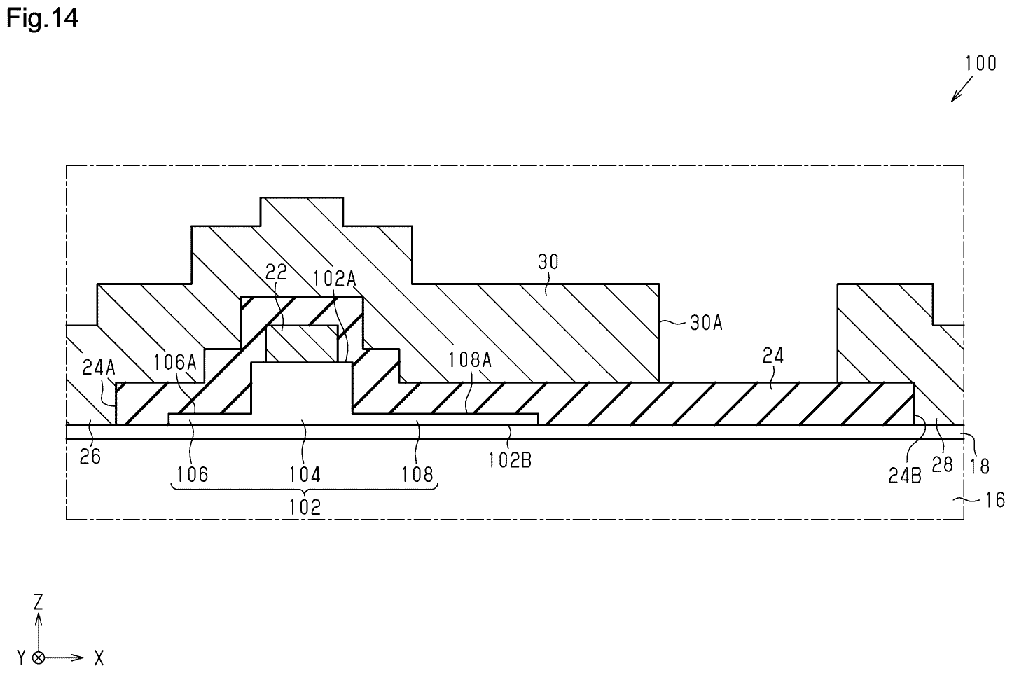

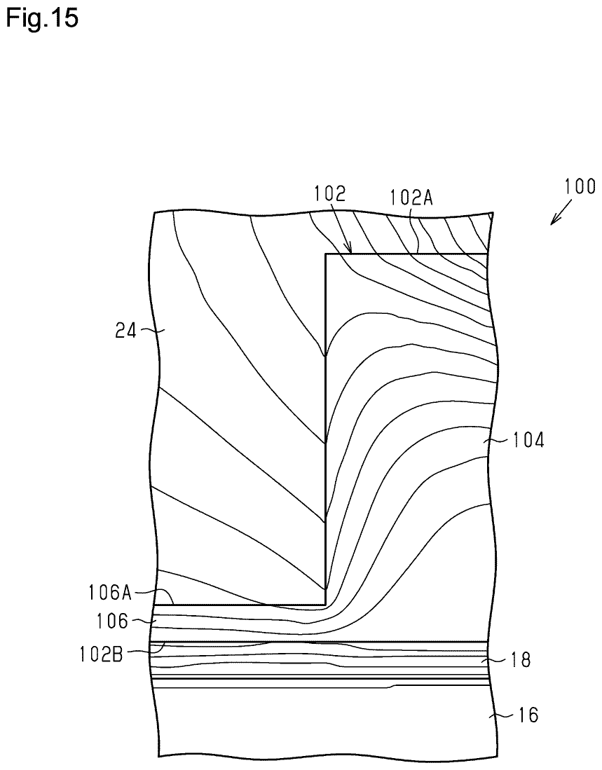

For comparison, the density of equipotential lines in a gate layer that does not have structures, such as the first intermediate portion 40 and the second intermediate portion 44, will be described with reference to FIGS. 14 and 15. FIG. 14 is a schematic cross-sectional view of a nitride semiconductor device 100 according to a comparative example. In FIG. 14, the same reference characters are given to those components that are the same as the corresponding components of the nitride semiconductor device 10 shown in FIG. 3. Such components will not be described in detail.

The nitride semiconductor device 100 shown in FIG. 14 includes a gate layer 102. The gate layer 102 includes an upper surface 102A on which the gate electrode 22 is formed and a bottom surface 102B that is in contact with the electron supply layer 18. The gate layer 102 includes a ridge 104 including the upper surface 102A, on which the gate electrode 22 is formed, and a source-side extension 106 and a drain-side extension 108 that are smaller in thickness than the ridge 104. Each of the ridge 104, the source-side extension 106, and the drain-side extension 108 is in contact with the electron supply layer 18, The source-side extension 106 and the drain-side extension 108 extend outward from the ridge 104 in plan view.

The source-side extension 106 includes an upper surface 106A parallel to the bottom surface 102B of the gate layer 102. The drain-side extension 108 includes an upper surface 108A parallel to the bottom surface 102B of the gate layer 102, The source-side extension 106 does not have a structure such as the first intermediate portion 40 shown in FIG. 3 and has a structure corresponding to the first step portion 38 shown in FIG. 3. The drain-side extension 108 does not have a structure such as the second intermediate portion 44 shown in FIG. 3 and has a structure corresponding to the second step portion 42 shown in FIG. 3.

FIG. 15 is an equipotential diagram showing a simulation result of an electric field distribution of the nitride semiconductor device 100 shown in FIG. 14. The simulation result shows the electric field distribution of the ridge 104 and a portion of the source-side extension 106 when a predetermined gate voltage (for example, 10 V) is applied to the gate electrode 22. Since the source-side extension 106 is smaller in thickness than the ridge 104, as shown in FIG. 15, the density of equipotential lines is relatively high in the source-side extension 106. Although not shown, the same applies to the drain-side extension 108 (refer to FIG. 14).

In the present embodiment, as shown in FIG. 3, the source-side extension 34 includes the first intermediate portion 40, and the drain-side extension 36 includes the second intermediate portion 44. This decreases the density of the equipotential lines in the source-side extension 34 and the drain-side extension 36 (particularly in the vicinity of the ridge 32).

As described above, the thicknesses of the source-side extension 34 and the drain-side extension 36 affect the on-resistance of the nitride semiconductor device 10. Hence, the cross-sectional areas of the first intermediate portion 40 and the second intermediate portion 44 in the plane orthogonal to the Y-axis direction may be set in consideration of the trade-off between the gate reliability and the on-resistance of the nitride semiconductor device 10.

In the nitride semiconductor device 10, the gate layer 20, on which the gate electrode 22 is disposed, is located closer to the first opening 24A, through which the source electrode 26 is in contact with the electron supply layer 18 than to the second opening 24B, through which the drain electrode 28 is in contact with the electron supply layer 18. Therefore, when a voltage is applied to the gate electrode 22, the electric field may be increased in a region located closer to the first opening 24A, in which the source electrode 26 is disposed, than to the second opening 24B, in which the drain electrode 28 is disposed. Thus, the gate reliability of the nitride semiconductor device 10 may be effectively improved (e.g., reduction in gate leakage current and improvement in voltage stress resistance) by reducing the density of the equipotential lines particularly in the source-side extension 34.

In this regard, in the nitride semiconductor device 10 of the present embodiment, the first intermediate portion 40 of the source-side extension 34 has a greater cross-sectional area than the second intermediate portion 44 of the drain-side extension 36 in the plane orthogonal to the Y-axis direction. This decreases the density of equipotential lines in the first intermediate portion 40 of the source-side extension 34 while limiting an increase in the on-resistance of the nitride semiconductor device 10 caused by the presence of the second intermediate portion 44 of the drain-side extension 36. Thus, the nitride semiconductor device 10 of the present embodiment improves the gate reliability while limiting an increase in on-resistance.

The nitride semiconductor device 10 of the present embodiment has the following advantages.

(1) The first intermediate portion 40 of the source-side extension 34 has a greater cross-sectional area than the second intermediate portion 44 of the drain-side extension 36 in the plane orthogonal to the Y-axis direction (second direction). This decreases the density of equipotential lines in the first intermediate portion 40 of the source-side extension 34 while limiting an increase in the on-resistance of the nitride semiconductor device 10 caused by the presence of the second intermediate portion 44 of the drain-side extension 36. Thus, the nitride semiconductor device 10 improves the gate reliability while limiting an increase in on-resistance.

(2) The thickness of the first intermediate portion 40 may be greater than or equal to the thickness of the first step portion 38 and less than the thickness of the ridge 32. The thickness of the second intermediate portion 44 may be greater than or equal to the thickness of the second step portion 42 and less than the thickness of the ridge 32. Thus, the density of equipotential lines in each of the intermediate portions 40 and 44 is decreased as compared to in the ridge 32, thereby improving the gate reliability of the nitride semiconductor device 10.

(3) The gate layer 20 may be located closer to the first opening 24A than to the second opening 24B. Thus, the distance between the gate electrode 22 and the drain electrode 28 is relatively increased, thereby inhibiting dielectric breakdown between the gate and the drain, which are prone to receiving a relatively large voltage.

(4) The drain-side extension 36 may be greater than the source-side extension 34 in dimension in the X-axis direction (first direction). This limits occurrence of gate leakage current in the region between the drain electrode 28 and the gate electrode 22 where a relatively large electric field is applied.

Modified Example of Gate Layer

First Modified Example

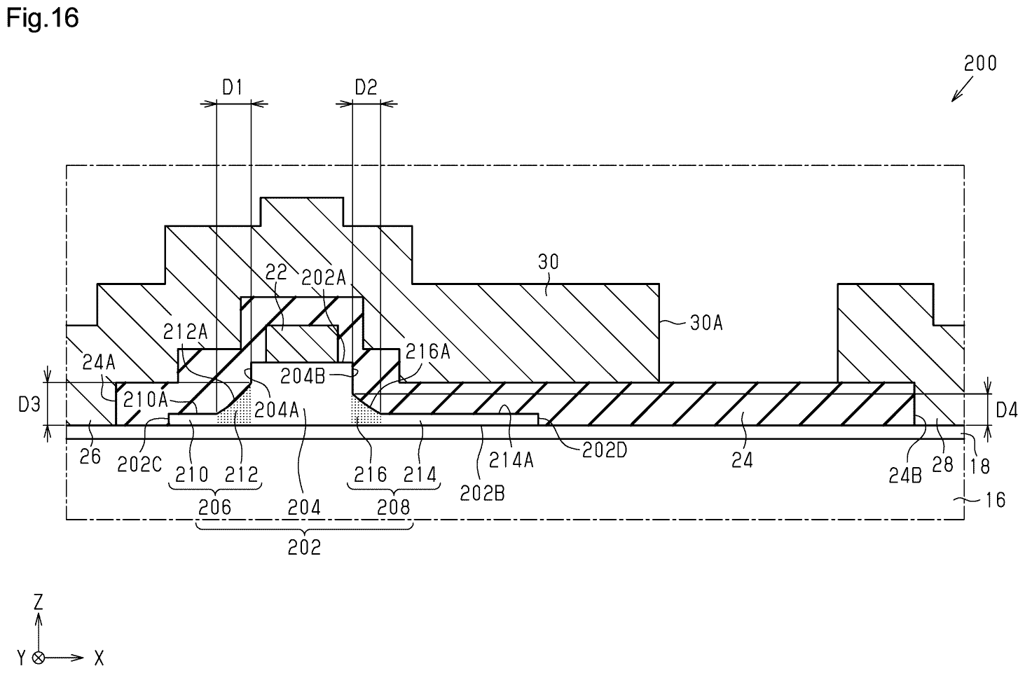

FIG. 16 is a schematic cross-sectional view of an exemplary nitride semiconductor device 200 including a first modified example of a gate layer. In FIG. 16, the same reference characters are given to those components that are the same as the corresponding components of the nitride semiconductor device 10 shown in FIGS. 2 and 3. Such components will not be described in detail.

As shown in FIG. 16, the nitride semiconductor device 200 includes a gate layer 202 formed on the electron supply layer 18 instead of the gate layer 20 shown in FIG. 3. The gate layer 202 and the gate layer 20 may be composed of the same material. The gate layer 202 is disposed between the first opening 24A and the second opening 24B. More specifically, the gate layer 202 may be disposed between the first opening 24A and the second opening 24B at a position closer to the first opening 24A than to the second opening 24B.

The gate layer 202 may include an upper surface 202A on which the gate electrode 22 is formed and a bottom surface 202B that is in contact with the electron supply layer 18. The gate layer 202 includes a ridge 204 including the upper surface 202A, on which the gate electrode 22 is formed, and a source-side extension 206 and a drain-side extension 208 that are smaller in thickness than the ridge 204. Each of the ridge 204, the source-side extension 206, and the drain-side extension 208 is in contact with the electron supply layer 18. The source-side extension 206 and the drain-side extension 208 extend outward from the ridge 204 in plan view.

The source-side extension 206 extends from the ridge 204 toward the first opening 24A. The source-side extension 206 does not reach the first opening 24A. The passivation layer 24 is disposed between the source-side extension 206 and the source electrode 26, which is embedded in the first opening 24A.

The drain-side extension 208 extends from the ridge 204 toward the second opening 24B. The drain-side extension 208 does not reach the second opening 24B. The passivation layer 24 is disposed between the drain-side extension 208 and the drain electrode 28, which is embedded in the second opening 24B.

The ridge 204 is disposed between the source-side extension 206 and the drain-side extension 208 and is formed integrally with the source-side extension 206 and the drain-side extension 208. Since the gate layer 202 includes the source-side extension 206 and the drain-side extension 208, the bottom surface 202B is greater in area than the upper 202A. In the example shown in FIG. 16, the drain-side extension 208 may extend outward from the ridge 204 longer than the source-side extension 206 in plan view. In other words, the drain-side extension 208 may be greater in dimension in the X-axis direction than the source-side extension 206. The source-side extension 206 may have a dimension in the X-axis direction that is greater than or equal to 0.05 μm and less than or equal to 0.3 μm. More preferably, the dimension of the source-side extension 206 in the X-axis direction may be, for example, greater than or equal to 0.2 μm and less than or equal to 0.3 μm. The drain-side extension 208 may have a dimension in the X-axis direction that is greater than or equal to 0.05 μm and less than or equal to 0.6 μm. More preferably, the dimension of the drain-side extension 208 in the X-axis direction may be, for example, greater than or equal to 0.2 μm and less than or equal to 0.6 μm.

The ridge 204 corresponds to a relatively thick portion of the gate layer 202. The ridge 204 may have a thickness that is greater than or equal to 50 nm and less than or equal to 200 nm. More preferably, the thickness of the ridge 204 may be, for example, greater than or equal to 80 nm and less than or equal to 150 nm. The thickness of the ridge 204 may be determined taking into consideration parameters including the gate threshold voltage. In an example, the thickness of the ridge 204 may be greater than 110 nm.

The source-side extension 206 includes a first step portion 210 including an upper surface 210A parallel to the bottom surface 202B of the gate layer 202 and a first intermediate portion 212 connecting the first step portion 210 to the ridge 204. The drain-side extension 208 includes a second step portion 214 including an upper surface 214A parallel to the bottom surface 202B of the gate layer 202 and a second intermediate portion 216 connecting the second step portion 214 to the ridge 204. The first step portion 210 includes a first end 202C of the gate layer 202 located toward the first opening 24A. The second step portion 214 includes a second end 2021) of the gate layer 202 located toward. the second opening 24B. The first end 202C and the second end 202D are ends of the gate layer 202 in the X-axis direction.

The first step portion 210 and the second step portion 214 may have dimensions similar to those of the first step portion 38 and the second step portion 42, respectively, shown in FIG. 3. The first intermediate portion 212 may have a thickness that gradually decreases as the ridge 204 becomes farther away. Also, the second intermediate portion 216 may have a thickness that gradually decreases as the ridge 204 becomes farther away.

The ridge 204 includes a first side surface 204A and a second side surface 204B opposite to the first side surface 204A. The first side surface 204A and the second side surface 204B may be flat. The first side surface 204A and the second side surface 204B intersect with the X-axis direction. The first side surface 204A and the second side surface 20413 may be orthogonal to the X-axis direction or may intersect with the X-axis direction at an angle other than right angles.

The first intermediate portion 212 includes a first intermediate surface 212A connecting the first side surface 204A of the ridge 204 and the upper surface 210A of the first step portion 210. The second intermediate portion 216 includes a second intermediate surface 216A connecting the second side surface 204B of the ridge 204 and the upper surface 214A of the second step portion 214.

In the example of FIG. 16, the first intermediate surface 212A may be ate inclined surface or a curved surface. That is, the first intermediate surface 212A may be inclined from the upper surface 210A of the first step portion 210. The first intermediate surface 212A may be inclined from the first side surface 204A of the ridge 204. The first intermediate surface 212A may be curved or may be flat. The first intermediate surface 212A may be at least partially curved.

Also, the second intermediate surface 216A may be an inclined surface or a curved surface. That is, the second intermediate surface 216A may be inclined from the upper surface 214A of the second step portion 214. The second intermediate surface 216A may be inclined from the second side surface 204B of the ridge 204. The second intermediate surface 216A may be curved or may be flat. The second intermediate surface 216A may be at least partially curved. In an example, at least one of the first intermediate surface 212A and the second intermediate surface 216A may be at least partially curved.

The first intermediate portion 212 has a cross-sectional area that is greater than that of the second intermediate portion 216 in a plane orthogonal to the Y-axis direction. The cross-sectional area of the first intermediate portion 212 corresponds to the area of a region (in FIG. 16, dot pattern region) between the first intermediate surface 212A and the bottom surface 202B of the gate layer 202. The cross-sectional area of the second intermediate portion 216 corresponds to the area of a region (in FIG. 16, dot pattern region) between the second intermediate surface 216A and the bottom surface 202B of the gate layer 202.

In the example of FIG. 16, a dimension D1 of the first intermediate portion 212 in the X-axis direction is larger than a dimension D2 of the second intermediate portion 216 in the X-axis direction. In an example, the dimension D1 of the first intermediate portion 212 may be greater than or equal to 5 nm and less than or equal to 100 nm in the X-axis direction. The dimension D2 of the second intermediate portion 216 may be greater than or equal to 5 nm and less than or equal to 100 nm in the X-axis direction. Also, a dimension D3 of the first intermediate portion 212 in the Z-axis direction is larger than a dimension D4 of the second intermediate portion 216 in the Z-axis direction. The dimension D3 of the first intermediate portion 212 in the Z-axis direction may be the thickness of the thickest part of the first intermediate portion 212. The dimension D4 of the second intermediate portion 216 in the Z-axis direction may be the thickness of the thickest part of the second intermediate portion 216. In an example, the thicknesses of each of the first intermediate portion 212 and the second intermediate portion 216 may be in a range from 10 nm to 80 nm. The dimension D3 of the first intermediate portion 212 in the Z-axis direction may be the thickness of the first intermediate portion 212 at a position adjacent to the ridge 204. The dimension D4 of the second intermediate portion 216 in the Z-axis direction may be the thickness of the second intermediate portion 216 at a position adjacent to the ridge 204. In this specification, the dimension D3 of the first intermediate portion 212 in the Z-axis direction may be simply referred to as the thickness of the first intermediate portion 212. The dimension D4 of the second intermediate portion 216 in the Z-axis direction may be simply referred to as the thickness of the second intermediate portion 216.

In another example, the dimension Di may be smaller than or equal to the dimension D2. In this case, the dimension D3 may be set to be larger than the dimension D4 so that the cross-sectional area of the first intermediate portion 212 is larger than the cross-sectional area of the second intermediate portion 216.

In another example, the dimension D3 may be smaller than or equal to the dimension D4. In this case, the dimension DI may be set to be larger than the dimension D2 so that the cross-sectional area of the first intermediate portion 212 is larger than the cross-sectional area of the second intermediate portion 216.

As described above, in the nitride semiconductor device 200, the first intermediate portion 212 has a greater cross-sectional area than the second intermediate portion 216 in the plane orthogonal to the Y-axis direction. This decreases the density of equipotential lines in the first intermediate portion 212 of the source-side extension 206 while limiting an increase in the on-resistance of the nitride semiconductor device 200 caused by the presence of the second intermediate portion 216 of the drain-side extension 208. Thus, the nitride semiconductor device 200 of the first modified example improves the gate reliability while limiting an increase in on-resistance.

Second Modified Example

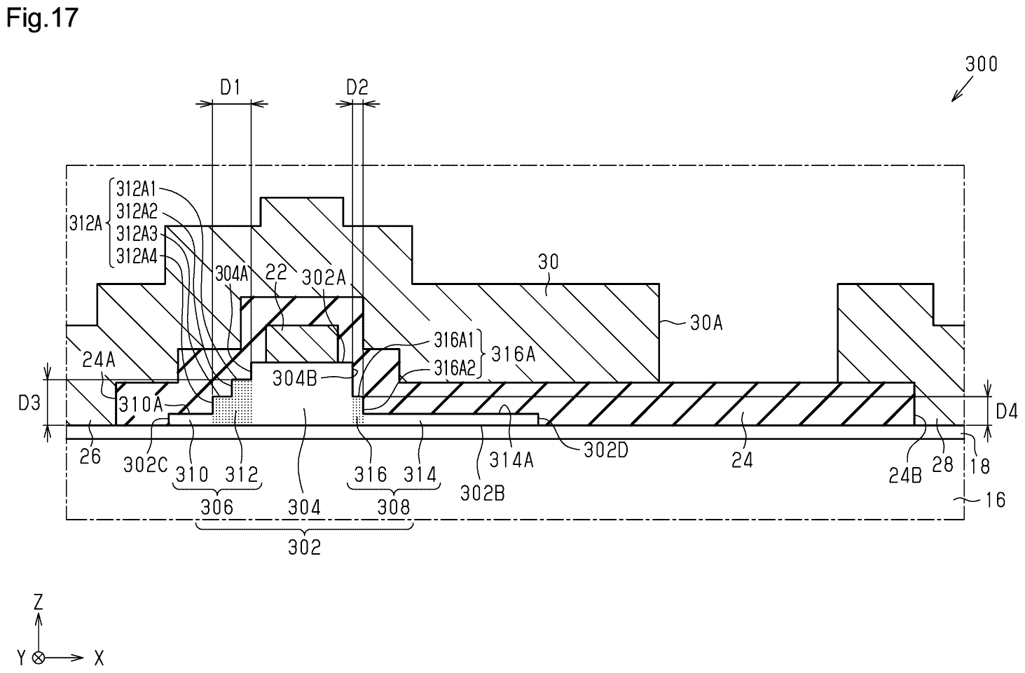

FIG. 17 is a schematic cross-sectional view of an exemplary nitride semiconductor device 300 including a second modified example of a gate layer. In FIG. 17, the same reference characters are given to those components that are the same as the corresponding components of the nitride semiconductor device 10 shown in FIGS. 2 and 3, Such components will not be described in detail.

As shown in FIG. 17, the nitride semiconductor device 300 includes a gate layer 302 formed on the electron supply layer 18 instead of the gate layer 20 shown in FIG. 3. The gate layer 302 and the gate layer 20 may be composed of the same material. The gate layer 302 is disposed between the first opening 24A and the second opening 24B. More specifically, the gate layer 302 may be disposed between the first opening 24A and the second opening 24B at a position closer to the first opening 24A than to the second opening 24B.

The gate layer 302 may include an upper surface 302A on which the gate electrode 22 is formed and a bottom surface 302B that is in contact with the electron supply layer 18.

The gate layer 302 includes a ridge 304 including the upper surface 302A, on which the gate electrode 22 is formed, and a source-side extension 306 and a drain-side extension 308 that are smaller in thickness than the ridge 304. Each of the ridge 304, the source-side extension 306, and the drain-side extension 308 is in contact with the electron supply layer 18. The source-side extension 306 and the drain-side extension 308 extend outward from the ridge 304 in plan view.

The source-side extension 306 extends from the ridge 304 toward the first opening 24A. The source-side extension 306 does not reach the first opening 24A. The passivation layer 24 is disposed between the source-side extension 306 and the source electrode 26, which is embedded in the first opening 24A.

The drain-side extension 308 extends from the ridge 304 toward the second opening 24B. The drain-side extension 308 does not reach the second opening 24B. The passivation layer 24 is disposed between the drain-side extension 308 and the drain electrode 28, which is embedded in the second opening 24B.

The ridge 304 is disposed between the source-side extension 306 and the drain-side extension 308 and is formed integrally with the source-side extension 306 and the drain-side extension 308. Since the gate layer 302 includes the source-side extension 306 and the drain-side extension 308, the bottom surface 302B is greater in area than the upper surface 302A. In the example shown in FIG. 17, the drain-side extension 308 may extend outward from the ridge 304 longer than the source-side extension 306 in plan view. In other words, the drain-side extension 308 may be greater in dimension in the X-axis direction than the source-side extension 306. The source-side extension 306 may have a dimension in the X-axis direction that is greater than or equal to 0.05 μm and less than or equal to 0.3 μm. More preferably, the dimension of the source-side extension 306 in the X-axis direction may be, for example, greater than or equal to 0.2 μm and less than or equal to 0.3 μm. The drain-side extension 308 may have a dimension in the X-axis direction that is greater than or equal to 0.05 μm and less than or equal to 0.6 μm. More preferably, the dimension of the drain-side extension 308 in the X-axis direction may be, for example, greater than or equal to 0.2 μm and less than or equal to 0.6 μm.

The ridge 304 corresponds to a relatively thick portion of the gate layer 302. The ridge 304 may have a thickness that is greater than or equal to 50 nm and less than or equal to 200 nm. More preferably, the thickness of the ridge 304 may be, for example, greater than or equal to 80 nm and less than or equal to 150 nm. The thickness of the ridge 304 may be determined taking into consideration parameters including the gate threshold voltage. In an example, the thickness of the ridge 304 may be greater than 110 nm.

The source-side extension 306 includes a first step portion 310 including an upper surface 310A parallel to the bottom surface 30213 of the gate layer 302 and a first intermediate portion 312 connecting the first step portion 310 to the ridge 304. The drain-side extension 308 includes a second step portion 314 including an upper surface 314A parallel to the bottom surface 302B of the gate layer 302 and a second intermediate portion 316 connecting the second step portion 314 to the ridge 304. The first step portion 310 includes a first end 302C of the gate layer 302 located toward the first opening 24A, The second step portion 314 includes a second end 302D of the gate layer 302 located toward the second opening 2411 The first end 302C and the second end 302D are ends of the gate layer 302 in the X-axis direction.

The first step portion 310 and the second step portion 314 may have dimensions similar to those of the first step portion 38 and the second step portion 42, respectively, shown in FIG. 3.

The ridge 304 includes a first side surface 304A and a second side surface 304B opposite to the first side surface 304A. The first side surface 304A and the second side surface 304B may be flat. The first side surface 304A and the second side surface 304B intersect with the X-axis direction. The first side surface 304A and the second side surface 304B may be orthogonal to the X-axis direction or may intersect with the X-axis direction at an angle other than right angles.

The first intermediate portion 312 includes a first intermediate surface 312A connecting the first side surface 304A of the ridge 304 and the upper surface 310A of the first step portion 310. The second intermediate portion 316 includes a second intermediate surface 316A connecting the second side surface 304B of the ridge 304 and the upper surface 314A of the second step portion 314.

In the example of FIG. 17, the first intermediate surface 312A may include two steps. More specifically, the first intermediate surface 312A may include a first upper surface 312A1, a first side surface 312A2, a second upper surface 312A3, and a second side surface 312A4 of the first intermediate portion 312. The first upper surface 312A1 and the second upper surface 312A3 of the first intermediate portion 312 may be parallel to the upper surface 310A of the first step portion 310. The first side surface 312A2 of the first intermediate portion 312 connects the first upper surface 312A1 and the second upper surface 312A3 of the first intermediate portion 312. The second side surface 312A4 of the first intermediate portion 312 connects the second upper surface 312A3 of the first intermediate portion 312 and the upper surface 310A of the first step portion 310. The first side surface 312A2 of the first intermediate portion 312 may extend vertically or obliquely between the first upper surface 312A1 and the second upper surface 312A3 of the first intermediate portion 312. The second side surface 312A4 of the first intermediate portion 312 may extend vertically or obliquely between the second upper surface 312A3 of the first intermediate portion 312 and the upper surface 310A of the first step portion 310. The first upper surface 312A1 of the first intermediate portion 312 is located between the upper surface 302A of the gate layer 302 and the second upper surface 312A3 of the first intermediate portion 312 in the Z-axis direction, The second upper surface 312A3 of the first intermediate portion 312 is located between the second upper surface 312A3 of the first intermediate portion 312 and the upper surface 310A of the first step portion 310 in the Z-axis direction.

The second intermediate surface 316A may include one step. More specifically, the second intermediate surface 316A may include an upper surface 316A1 and a side surface 316A2 of the second intermediate portion 316. The upper surface 316A1 of the second intermediate portion 316 may be parallel to the upper surface 314A of the second step portion 314. The side surface 316A2 of the second intermediate portion 316 connects the upper surface 316A1 of the second intermediate portion 316 and the upper surface 314A of the second step portion 314. The side surface 316A2 of the second intermediate portion 316 may extend vertically or obliquely between the upper surface 316A1 of the second intermediate portion 316 and the upper surface 314A of the second step portion 314. The upper surface 316A1 of the second intermediate portion 316 is located between the upper surface 302A of the gate layer 302 and the upper surface 314A of the second step portion 314 in the Z-axis direction.

The first intermediate portion 312 has a cross-sectional area that is greater than that of the second intermediate portion 316 in a plane orthogonal to the Y-axis direction. The cross-sectional area of the first intermediate portion 312 corresponds to the area of a region (in FIG. 17, dot pattern region) between the first intermediate surface 312A and the bottom surface 302B of the gate layer 302, The cross-sectional area of the second intermediate portion 316 corresponds to the area of a region (in FIG. 17, dot pattern region) between the second intermediate surface 316A and the bottom surface 302B of the gate layer 302.

In the example of FIG. 17, a dimension D1 of the first intermediate portion 312 in the X-axis direction is larger than a dimension D2 of the second intermediate portion 316 in the X-axis direction. In an example, the dimension DI of the first intermediate portion 312 may be greater than or equal to 5 nm and less than or equal to 100 nm in the X-axis direction. The dimension D2 of the second intermediate portion 316 may be greater than or equal to 5 nm and less than or equal to 100 nm in the X-axis direction. Also, a dimension D3 of the first intermediate portion 312 in the Z-axis direction is larger than a dimension D4 of the second intermediate portion 316 in the Z-axis direction. The dimension D3 of the first intermediate portion 312 in the Z-axis direction may be the thickness of the thickest part of the first intermediate portion 312. The dimension D4 of the second intermediate portion 316 in the Z-axis direction may be the thickness of the thickest part of the second intermediate portion 316. In an example, the thicknesses of each of the first intermediate portion 312 and the second intermediate portion 316 may be in a range from 10 nm to 80 nm. The dimension D3 of the first intermediate portion 312 in the Z-axis direction may be the thickness of the first intermediate portion 312 at a position adjacent to the ridge 304, The dimension D4 of the second intermediate portion 316 in the Z-axis direction may be the thickness of the second intermediate portion 316 at a position adjacent to the ridge 304. In this specification, the dimension D3 of the first intermediate portion 312 in the Z-axis direction may be simply referred to as the thickness of the first intermediate portion 312. The dimension D4 of the second intermediate portion 316 in the Z-axis direction may be simply referred to as the thickness of the second intermediate portion 316.

In another example, the dimension D1 may be smaller than or equal to the dimension D2. In this case, the dimension D3 may be set to be larger than the dimension D4 so that the cross-sectional area of the first intermediate portion 312 is greater than the cross-sectional area of the second intermediate portion 316.

in another example, the dimension D3 may be smaller than or equal to the dimension D4. In this case, the dimension D1 may be set to be larger than the dimension D2 so that the cross-sectional area of the first intermediate portion 312 is greater than the cross-sectional area of the second intermediate portion 316.

As described above, in the nitride semiconductor device 300, the first intermediate portion 312 has a greater cross-sectional area than the second intermediate portion 316 in the plane orthogonal to the Y-axis direction. This decreases the density of equipotential lines in the first intermediate portion 312 of the source-side extension 306 while limiting an increase in the on-resistance of the nitride semiconductor device 300 caused by the presence of the second intermediate portion 316 of the drain-side extension 308. Thus, the nitride semiconductor device 300 of the second modified example improves the gate reliability while limiting an increase in on-resistance.

Third Modified Example

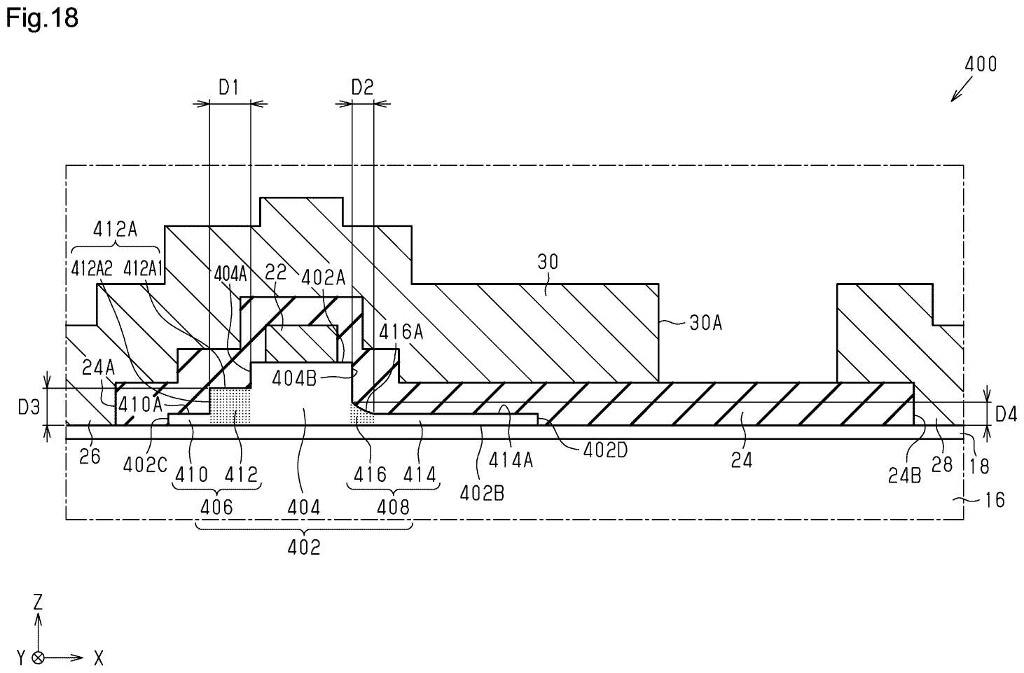

FIG. 18 is a schematic cross-sectional view of an exemplary nitride semiconductor device 400 including a third modified example of a gate layer. In FIG. 18, the same reference characters are given to those components that are the same as the corresponding components of the nitride semiconductor device 10 shown in FIGS. 2 and 3. Such components will not be described in detail.

As shown in FIG. 18, the nitride semiconductor device 400 includes a gate layer 402 formed on the electron supply layer 18 instead of the gate layer 20 shown in FIG. 3. The gate layer 402 and the gate layer 20 may be composed of the same material. The gate layer 402 is disposed between the first opening 24A and the second opening 24B. More specifically, the gate layer 402 may be disposed between the first opening 24A and the second opening 24B at a position closer to the first opening 24A than to the second opening 24B.

The gate layer 402 may include an upper surface 402A on which the gate electrode 22 is formed and a bottom surface 402B that is in contact with the electron supply layer 18. The gate layer 402 includes a ridge 404 including the upper surface 402A, on which the gate electrode 22 is formed, and a source-side extension 406 and a drain-side extension 408 that are smaller in thickness than the ridge 404, Each of the ridge 404, the source-side extension 406, and the drain-side extension 408 is in contact with the electron supply layer 18. The source-side extension 406 and the drain-side extension 408 extend outward from the ridge 404 in plan view.

The source-side extension 406 extends from the ridge 404 toward the first opening 24A. The source-side extension 406 does not reach the first opening 24A. The passivation layer 24 is disposed between the source-side extension 406 and the source electrode 26, which is embedded in the first opening 24A.

The drain-side extension 408 extends from the ridge 404 toward the second opening 241. The drain-side extension 408 does not reach the second opening 24B. The passivation layer 24 is disposed between the drain-side extension 408 and the drain electrode 28, which is embedded in the second opening 24B.

The ridge 404 is disposed between the source-side extension 406 and the drain-side extension 408 and is formed integrally with the source-side extension 406 and the drain-side extension 408. Since the gate layer 402 includes the source-side extension 406 and the drain-side extension 408, the bottom surface 402B is greater in area than the upper surface 402A. In the example shown in FIG. 18, the drain-side extension 408 may extend outward from the ridge 404 longer than the source-side extension 406 in plan view. In other words, the drain-side extension 408 may be greater in dimension in the X-axis direction than source-side extension 406. The source-side extension 406 may have a dimension in the X-axis direction that is greater than or equal to 0.05 μm and less than or equal to 0.3 μm. More preferably, the dimension of the source-side extension 406 in the X-axis direction may be, for example, greater than or equal to 0.2 μm and less than or equal to 0.3 μm. The drain-side extension 408 may have a dimension in the X-axis direction that is greater than or equal to 0.05 μm and less than or equal to 0.6 μm. More preferably, the dimension of the drain-side extension 408 in the X-axis direction may be, for example, greater than or equal to 0.2 μm and less than or equal to 0.6 μm.

The ridge 404 corresponds to a relatively thick portion of the gate layer 402. The ridge 404 may have a thickness that is greater than or equal to 50 nm and less than or equal to 200 nm. More preferably, the thickness of the ridge 404 may be, for example, greater than or equal to 80 nm and less than or equal to 150 nm. The thickness of the ridge 404 may be determined taking into consideration parameters including the gate threshold voltage. In an example, the thickness of the ridge 404 may be greater than 110 nm.

The source-side extension 406 includes a first step portion 410 including an upper surface 410A parallel to the bottom surface 402B of the gate layer 402 and a first intermediate portion 412 connecting the first step portion 410 to the ridge 404. The drain-side extension 408 includes a second step portion 414 including an upper surface 414A parallel to the bottom surface 402B of the gate layer 402 and a second intermediate portion 416 connecting the second step portion 414 to the ridge 404. The first step portion 410 includes a first end 402C of the gate layer 402 located toward the first opening 24A. The second step portion 414 includes a second end 402D of the gate layer 402 located toward the second opening 24B. The first end 402C and the second end 402D are ends of the gate layer 402 in the X-axis direction.

The first step portion 410 and the second step portion 414 may have dimensions similar to those of the first step portion 38 and the second step portion 42, respectively, shown in FIG. 3.

The ridge 404 includes a first side surface 404A and a second side surface 404B opposite to the first side surface 404A. The first side surface 404A and the second side surface 404B may be flat The first side surface 404A and the second side surface 404B intersect with the X-axis direction. The first side surface 404A and the second side surface 40413 may be orthogonal to the X-axis direction or may intersect with the X-axis direction at an angle other than right angles.

The first intermediate portion 412 includes a first intermediate surface 412A connecting the first side surface 404A of the ridge 404 and the upper surface 410A of the first step portion 410. The second intermediate portion 416 includes a second intermediate surface 416A connecting the second side surface 4046 of the ridge 404 and the upper surface 414A of the second step portion 414.

In the example of FIG. 18, the first intermediate surface 412A may include one step. More specifically, the first intermediate surface 412A may include an upper surface 412A1 and a side surface 412A2 of the first intermediate portion 412. The upper surface 412A1 of the first intermediate portion 412 may be parallel to the upper surface 410A of the first step portion 410. The side surface 412A2 of the first intermediate portion 412 connects the upper surface 412A1 of the first intermediate portion 412 and the upper surface 410A of the first step portion 410. The side surface 412A2 of the first intermediate portion 412 may extend vertically or obliquely between the upper surface 412A1 of the first intermediate portion 412 and the upper surface 410A of the first step portion 410. The upper surface 412A1 of the first intermediate portion 412 is located between the upper surface 402A of the gate layer 402 and the upper surface 410A of the first step portion 410 in the Z-axis direction.

The second intermediate surface 416A may be an inclined surface or a curved surface. That is, the second intermediate surface 416A may be inclined from the second side surface 404B of the ridge 404 and the upper surface 414A of the second step portion 414. The second intermediate surface 416A may be curved or may be flat. The second intermediate surface 416A may be at least partially curved.

The first intermediate portion 412 has a cross-sectional area that is greater than that of the second intermediate portion 416 in a plane orthogonal to the Y-axis direction. The cross-sectional area of the first intermediate portion 412 corresponds to the area of a region (in FIG. 18, dot pattern region) between the first intermediate surface 412A and the bottom surface 402B of the gate layer 402. The cross-sectional area of the second intermediate portion 416 corresponds to the area of a region (in FIG. 18, dot pattern region) between the second intermediate surface 416A and the bottom surface 402B of the gate layer 402.

In the example of FIG. 18, a dimension D1 of the first intermediate portion 412 in the X-axis direction is larger than a dimension D2 of the second intermediate portion 416 in the X-axis direction. In an example, the dimension D1 of the first intermediate portion 412 may be greater than or equal to 5 nm and less than or equal to 100 nm in the X-axis direction. The dimension D2 of the second intermediate portion 416 may be greater than or equal to 5 nm and less than or equal to 100 nm in the X-axis direction. Also, a dimension D3 of the first intermediate portion 412 in the Z-axis direction is larger than a dimension D4 of the second intermediate portion 416 in the Z-axis direction. The dimension D3 of the first intermediate portion 412 in the Z-axis direction may be the thickness of the thickest part of the first intermediate portion 412. The dimension D4 of the second intermediate portion 416 in the Z-axis direction may be the thickness of the thickest part of the second intermediate portion 416, in an example, the thicknesses of each of the first intermediate portion 412 and the second intermediate portion 416 may be in a range from 10 nm to 80 nm. The dimension D3 of the first intermediate portion 412 in the Z-axis direction may be the thickness of the first intermediate portion 412 at a position adjacent to the ridge 404. The dimension D4 of the second intermediate portion 416 in the Z-axis direction may be the thickness of the second intermediate portion 416 at a position adjacent to the ridge 404. In this specification, the dimension D3 of the first intermediate portion 412 in the Z-axis direction may be simply referred to as the thickness of the first intermediate portion 412. The dimension D4 of the second intermediate portion 416 in the Z-axis direction may be simply referred to as the thickness of the second intermediate portion 416.

In another example, the dimension D1 may be smaller than or equal to the dimension D2. In this case, the first intermediate portion 412 including the first intermediate surface 412A having one step may still have a greater cross-sectional area than the second intermediate portion 416 including the second intermediate surface 416A having no step.

In another example, the dimension D3 may be smaller than or equal to the dimension D4. In this case, the first intermediate portion 412 including the first intermediate surface 412A having one step may still have a greater cross-sectional area than the second intermediate portion 416 including the second intermediate surface 416A having no step.

As described above, in the nitride semiconductor device 400, the first intermediate portion 412 has a greater cross-sectional area than the second intermediate portion 416 in the plane orthogonal to the Y-axis direction. This decreases the density of equipotential lines in the first intermediate portion 412 of the source-side extension 406 while limiting an increase in the on-resistance of the nitride semiconductor device 400 caused by the presence of the second intermediate portion 416 of the drain-side extension 408. Thus, the nitride semiconductor device 400 of the third modified example improves the gate reliability while limiting an increase in on-resistance.

Other Modified Examples

Each of the embodiments and the modified examples described above may be modified as follows.

In the nitride semiconductor device 10 shown in FIG. 3, at least one of the side surface 40A2 of the first intermediate portion 40 and the side surface 44A2 of the second intermediate portion 44 may be at least partially curved.

In the nitride semiconductor device 300, the number of steps in each of the first intermediate surface 312A and the second intermediate surface 316A is not limited to that in the example shown in FIG. 17. Each of the first intermediate surface 312A and the second intermediate surface 316A may include one or more steps. The number of steps in the first intermediate surface 312A may be greater than or equal to the number of steps in the second intermediate surface 316A. In an example, the first intermediate surface 312A may include three steps, and the second intermediate surface 316A may include two steps or less.

In the nitride semiconductor device 400 shown in FIG. 18, the first intermediate surface 412A may include two or more steps.

The manufacturing steps for forming the gate layer having a desired shape are not limited to those described above. In an example, an asymmetric shape of the gate layer may be obtained by using two or more nitride semiconductor materials that differ from each other in chemical stability.

One or more of the various examples described in this specification may be combined within a range where there is no technical inconsistency.

In this specification, “at least one of A and B” should be understood to mean “only A, or only B, or both A and B”.

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer. For example, a structure in which the electron supply layer 18 is formed on the electron transit layer 16 includes a structure in which an intermediate layer is disposed between the electron supply layer 18 and the electron transit layer 16 to stably form the 2DEG.

The directional terms used in the present disclosure such as “vertical,” “horizontal,” “above,” “below,” “top,” “bottom,” “front,” “back,” “longitudinal,” “lateral,” “left,” “right,” “front,” and “back” will depend upon a particular orientation of the device being described and illustrated. The present disclosure may include various alternative orientations. Therefore, the directional terms should not be narrowly construed.

In an example, the Z-axis direction as referred to in the present disclosure does not necessarily have to be the vertical direction and does not necessarily have to fully conform to the vertical direction. In the structures according to the present disclosure (e.g., the structure shown in FIG. 2), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

Clauses

The technical aspects that are understood from the present disclosure will hereafter be described. It should be noted that, for the purpose of facilitating understanding with no intention to limit, elements described in clauses are given the reference characters of the corresponding elements of the embodiments. The reference characters used as examples to facilitate understanding, and the elements in each clause are not limited to those elements given with the reference characters.

1. A nitride semiconductor device, including:
an electron transit layer (16) composed of a nitride semiconductor; an electron supply layer (18) formed on the electron transit layer (16) and composed of a nitride semiconductor having a band gap that is larger than that of the electron transit layer (16);
a gate layer (20; 202; 302; 402) formed on a portion of the electron supply layer (18) and composed of a nitride semiconductor including an acceptor impurity;
a gate electrode (22) formed on the gate layer (20; 202; 302; 402); a passivation layer (24) covering the electron supply layer (18), the gate layer (20; 202; 302; 402), and the gate electrode (22) and including a first opening (24A) and a second opening (24B) that are separated from each other in a first direction;
a source electrode (26) in contact with the electron supply layer (18) through the first opening (24A); and
a drain electrode (28) in contact with the electron supply layer (18) through the second opening (24B), in which
the gate layer (20; 202; 302; 402) is disposed between the first opening (24A) and the second opening (24B) and extends in a second direction orthogonal to the first direction in plan view and includes an upper surface (20A; 202A; 302A; 402A) on which the gate electrode (22) is formed and a bottom surface (20B; 202B; 302B; 402B) in contact with the electron supply layer (18),
the gate layer (20; 202; 302; 402) includes
a ridge (32; 204; 304; 404) in contact with the electron supply layer (18) and including the upper surface (20A; 202A; 302A; 402A) of the gate layer (20; 202; 302; 402),
a source-side extension (34; 206; 306; 406) extending from the ridge (32; 204; 304; 404) toward the first opening (24A) in contact with the electron supply layer (18). the source-side extension (34; 206; 306; 406) being smaller in thickness than the ridge (32; 204; 304; 404), and
a drain-side extension (36; 208; 308; 408) extending from the ridge (32; 204; 304; 404) toward the second opening (24B) in contact with the electron supply layer (18), the drain-side extension (36; 208; 308; 408) being smaller in thickness than the ridge (32; 204; 304; 404),
the source-side extension (34; 206; 306; 406) includes a first step portion (38; 210; 310; 410) including an upper surface (38A; 210A; 310A; 410A) parallel to the bottom surface (20B; 202B; 302B; 402B) of the gate layer (20; 202; 302; 402) and a first intermediate portion (40; 212; 312; 412) connecting the first step portion (38; 210; 310; 410) to the ridge (32; 204; 304; 404),
the drain-side extension (36; 208; 308; 408) includes a second step portion (42; 214; 314; 414) including an upper surface (42A; 214A; 314A; 414A) parallel to the bottom surface (20B; 202B; 302B; 402B) of the gate layer (20; 202; 302; 402) and a second intermediate portion (44; 216; 316; 416) connecting the second step portion (42; 214; 314; 414) to the ridge (32; 204; 304; 404), and
the first intermediate portion (40; 212; 312; 412) has a cross-sectional area that is greater than that of the second intermediate portion (44; 216; 316; 416) in a plane orthogonal to the second direction.

2. The nitride semiconductor device according to clause 1, in which
the ridge (32; 204; 304; 404) includes a first side surface (32A; 204A; 304A; 404A) and a second side surface (3213; 20413; 30413; 40413) opposite to the first side surface (32A; 204A; 304A; 404A),
the first intermediate portion (40; 212; 312; 412) includes a first intermediate surface (40A; 212A; 312A; 412A) connecting the first side surface (32A; 204A; 304A; 404A) of the ridge (32; 204; 304; 404) and the upper surface (38A; 210A; 310A; 410A) of the first step portion (38; 210; 310; 410), and
the second intermediate portion (44; 216; 316; 416) includes a second intermediate surface (44A; 216A; 316A; 416A) connecting the second side surface (32B; 204B; 304B; 404B) of the ridge (32; 204; 304; 404) and the upper surface (42A; 214A; 314A; 414A) of the second step portion (42; 214; 314; 414).

3. The nitride semiconductor device according to clause 2, in which the first side surface (32A; 204A; 304A; 404A) and the second side surface (32B; 204B; 304B; 404B) are flat.

4. The nitride semiconductor device according to clause 2 or 3, in which each of the first intermediate surface (40A; 312A) and the second intermediate surface (44A; 316A) includes one or more steps, and
the number of steps in the first intermediate surface (40A; 312A) is greater than or equal to the number of steps in the second intermediate surface (44A; 316A).

5. The nitride semiconductor device according to clause 2 or 3, in which
the first intermediate surface (40A) includes an upper surface (40A1) and a side surface (40A2) of the first intermediate portion (40),
the upper surface (40A1) of the first intermediate portion (40) is parallel to the upper surface (38A) of the first step portion (38),
the side surface (40A2) of the first intermediate portion (40) connects the upper surface (40A1) of the first intermediate portion (40) and the upper surface (38A) of the first step portion (38),
the second intermediate surface (44A) includes an upper surface (44A1) and a side surface (44A2) of the second intermediate portion (44),
the upper surface (44A1) of the second intermediate portion (44) is parallel to upper surface (42A) of the second step portion (42), and
the side surface (44A2) of the second intermediate portion (44) connects the upper surface (44A1) of the second intermediate portion (44) and the upper surface (42A) of the second step portion (42).

6. The nitride semiconductor device according to clause 2 or 3, in which
the first intermediate surface (212A) is inclined from the upper surface (210A) of the first step portion (210), and
the second intermediate surface (216A) is inclined from the upper surface (214A) of the second step portion (214).

7. The nitride semiconductor device according to clause 2 or 3, in which
the first intermediate surface (412A) includes one or more steps, and the second intermediate surface (416A) is inclined from the upper surface (414A) of the second step portion (414).

8. The nitride semiconductor device according to clause 2 or 3, in which at least one of the first intermediate surface (40A: 212A; 312A; 412A) or the second intermediate surface (44A; 216A; 316A; 416A) is at least partially curved.

9. The nitride semiconductor device according to any one of clauses 1 to 8, in which a dimension (D1) of the first intermediate portion (40; 212; 312; 412) in the first direction is larger than a dimension (D2) of the second intermediate portion (44; 216; 316; 416) in the first direction.

10. The nitride semiconductor device according to any one of clauses 1 to 9, in which a thickness (D3) of the first intermediate portion (40; 212; 312; 412) at a position adjacent to the ridge (32; 204; 304; 404) is greater than a thickness (D4) of the second intermediate portion (44; 216; 316; 416) at a position adjacent to the ridge (32; 204; 304; 404).

11. The nitride semiconductor device according to any one of clauses 1 to 10, in which
the first intermediate portion (40; 212; 312; 412) is greater than or equal to than the first step portion (38; 210; 310; 410) and less than the ridge (32; 204; 304; 404) in thickness, and
the second intermediate portion (44; 216; 316; 416) is greater than or equal to the second step portion (42; 214; 314; 414) and less than the ridge (32; 204; 304; 404) in thickness.

12. The nitride semiconductor device according to any one of clauses 1 to 11 in which
the ridge (32; 204; 304; 404) has a thickness that is greater than or equal to 50 nm and less than or equal to 200 nm, and
each of the first step portion (38; 210; 310; 410) and the second step portion (42; 214; 314; 414) has a thickness that is greater than or equal to 5 nm and less than or equal to 25 nm.

13. The nitride semiconductor device according to any one of clauses 1 to 12, in which each of the first intermediate portion (40; 212; 312; 412) and the second intermediate portion (44; 216; 316; 416) has a thickness in a range from 10 nm to 80 nm.

14. The nitride semiconductor device according to any one of clauses 1 to 13, in which the first step portion (38; 210; 310; 410) and the second step portion (42; 214; 314; 414) are equal in thickness.

15. The nitride semiconductor device according to any one of clauses 1 to 14, in which the gate layer (20; 202; 302; 402) is disposed closer to the first opening (24A) than the second opening (24B).

16. The nitride semiconductor device according to any one of clauses 1 to 15, in which the drain-side extension (36; 208; 308; 408) is greater than the source-side extension (34; 206; 306; 406) in dimension in the first direction.

17. The nitride semiconductor device according to any one of clauses 1 to 16, in which
the source-side extension (34; 206; 306; 406) has a dimension in the first direction that is greater than or equal to 0.05 μm and less than or equal to 0.3 μm, and the drain-side extension (36; 208; 308; 408) has a dimension in the first direction that is greater than or equal to 0.05 μm and less than or equal to 0.6 μm.

18. The nitride semiconductor device according to any one of clauses 1 to 17, in which
the first intermediate portion (40; 212; 312; 412) has a dimension (D1) in the first direction that is greater than or equal to 5 nm and less than or equal to 100 nm, and the second intermediate portion (44; 216; 316; 416) has a dimension (D2) in the first direction that is greater than or equal to 5 nm and less than or equal to 100 nm.

19. The nitride semiconductor device according to any one of clauses 1 to 18, in which
the first step portion (38; 210; 310; 410) includes a first end (20C; 202C; 302(; 402C) of the gate layer (20; 202; 302; 402) located toward the first opening (24A), and
the second step portion (42; 214; 314; 414) includes a second end (20D; 202D; 302D; 402D) of the gate layer (20; 202; 302; 402) located toward the second opening (24B).

20. The nitride semiconductor device according to any one of clauses 1 to 19, in which
the electron transit layer (16) includes GaN,
the electron supply layer (18) includes AlₓGa₁₋ₓN, where 0<x<0.3, and
the gate layer (20; 202; 302; 402) includes GaN containing at least one of Mg or Zn as an impurity.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
an electron transit layer composed of a nitride semiconductor;
an electron supply layer formed on the electron transit layer and composed of a nitride semiconductor having a band gap that is larger than that of the electron transit layer;
a gate layer formed on a portion of the electron supply layer and composed of a nitride semiconductor including an acceptor impurity;
a gate electrode formed on the gate layer;
a passivation layer covering the electron supply layer, the gate layer, and the gate electrode and including a first opening and a second opening that are separated from each other in a first direction;
a source electrode in contact with the electron supply layer through the first opening; and
a drain electrode in contact with the electron supply layer through the second opening, wherein
the gate layer is disposed between the first opening and the second opening and extends in a second direction orthogonal to the first direction in plan view and includes an upper surface on which the gate electrode is formed and a bottom surface in contact with the electron supply layer,
the gate layer includes
a ridge in contact with the electron supply layer and including the upper surface of the gate layer,
a source-side extension extending from the ridge toward the first opening in contact with the electron supply layer, the source-side extension being smaller in thickness than the ridge, and
a drain-side extension extending from the ridge toward the second opening in contact with the electron supply layer, the drain-side extension being smaller in thickness than the ridge,
the source-side extension includes a first step portion including an upper surface parallel to the bottom surface of the gate layer and a first intermediate portion connecting the first step portion to the ridge,
the drain-side extension includes a second step portion including an upper surface parallel to the bottom surface of the gate layer and a second intermediate portion connecting the second step portion to the ridge, and
the first intermediate portion has a cross-sectional area that is greater than that of the second intermediate portion in a plane orthogonal to the second direction.

2. The nitride semiconductor device according to claim 1, wherein
the ridge includes a first side surface and a second side surface opposite to the first side surface,
the first intermediate portion includes a first intermediate surface connecting the first side surface of the ridge and the upper surface of the first step portion, and
the second intermediate portion includes a second intermediate surface connecting the second side surface of the ridge and the upper surface of the second step portion.

3. The nitride semiconductor device according to claim 2, wherein the first side surface and the second side surface are flat.

4. The nitride semiconductor device according to claim 2, wherein
each of the first intermediate surface and the second intermediate surface includes one or more steps, and
the number of steps in the first intermediate surface is greater than or equal to the number of steps in the second intermediate surface.

5. The nitride semiconductor device according to claim 2, wherein
the first intermediate surface includes an upper surface and a side surface of the first intermediate portion,
the upper surface of the first intermediate portion is parallel to the upper surface of the first step portion,
the side surface of the first intermediate portion connects the upper surface of the first intermediate portion and the upper surface of the first step portion,
the second intermediate surface includes an upper surface and a side surface of the second intermediate portion,
the upper surface of the second intermediate portion is parallel to the upper surface of the second step portion, and
the side surface of the second intermediate portion connects the upper surface of the second intermediate portion and the upper surface of the second step portion.

6. The nitride semiconductor device according to claim 2, wherein
the first intermediate surface is inclined from the upper surface of the first step portion, and
the second intermediate surface is inclined from the upper surface of the second step portion.

7. The nitride semiconductor device according to claim 2, wherein
the first intermediate surface includes one or more steps, and
the second intermediate surface is inclined from the upper surface of the second step portion.

8. The nitride semiconductor device according to claim 2, wherein at least one of the first intermediate surface or the second intermediate surface is at least partially curved.

9. The nitride semiconductor device according to claim 1, wherein a dimension of the first intermediate portion in the first direction is larger than a dimension of the second intermediate portion in the first direction.

10. The nitride semiconductor device according to claim 1, wherein a thickness of the first intermediate portion at a position adjacent to the ridge is greater than a thickness of the second intermediate portion at a position adjacent to the ridge.

11. The nitride semiconductor device according to claim 1, wherein
the first intermediate portion is greater than or equal to than the first step portion and less than the ridge in thickness, and
the second intermediate portion is greater than or equal to the second step portion and less than the ridge in thickness.

12. The nitride semiconductor device according to claim 1, wherein the ridge has a thickness that is greater than or equal to 50 nm and less than or equal to 200 nm, and
each of the first step portion and the second step portion has a thickness that is greater than or equal to 5 nm and less than or equal to 25 nm.

13. The nitride semiconductor device according to claim 1, wherein each of the first intermediate portion and the second intermediate portion has a thickness in a range from 10 nm to 80 nm.

14. The nitride semiconductor device according to claim 1, wherein the first step portion and the second step portion are equal in thickness.

15. The nitride semiconductor device according to claim 1, wherein the gate layer is disposed closer to the first opening than the second opening.

16. The nitride semiconductor device according to claim 1, wherein the drain-side extension is greater than the source-side extension in dimension in the first direction.

17. The nitride semiconductor device according to claim 1, wherein
the source-side extension has a dimension in the first direction that is greater than or equal to 0.05 μm and less than or equal to 0.3 μm, and
the drain-side extension has a dimension in the first direction that is greater than or equal to 0.05 μm and less than or equal to 0.6 μm.

18. The nitride semiconductor device according to claim 1, wherein
the first intermediate portion has a dimension in the first direction that is greater than or equal to 5 nm and less than or equal to 100 nm, and
the second intermediate portion has a dimension in the first direction that is greater than or equal to 5 nm and less than or equal to 100 nm.

19. The nitride semiconductor device according to claim 1, wherein
the first step portion includes a first end of the gate layer located toward the first opening, and
the second step portion includes a second end of the gate layer located toward the second opening.

20. The nitride semiconductor device according to claim 1, wherein
the electron transit layer includes GaN,
the electron supply layer includes AlₓGa₁₋ₓN, where 0<x<0.3, and
the gate layer includes GaN containing at least one of Mg or Zn as an impurity.
